(19) United States
(12) Patent Application Publication
(10) Pub. No.: US 2026/0068390 A1
(43) Pub. Date: Mar. 5, 2026

(54) STRETCHABLE DISPLAY DEVICE

(71) Applicant: LG Display Co., Ltd., Seoul (KR)

(72) Inventors: Jinhyung JUNG, Goyang-si (KR); TaeWoon KO, Seoul (KR)

(73) Assignee: LG Display Co., Ltd., Seoul (KR)

(21) Appl. No.: 19/281,475

(22) Filed: Jul. 25, 2025

(30) Foreign Application Priority Data
Aug. 30, 2024 (KR) 10-2024-0117844

(51) Int. Cl. H10H 29/49

(52) U.S. Cl. CPC H10H 29/49

(57) ABSTRACT

A stretchable display device according to one or more examples includes a lower substrate, a plurality of pixels including a plurality of sub pixels, a plurality of island substrates disposed on the lower substrate and spaced apart from each other, each corresponding to a respective pixel, a plurality of connection lines which electrically connects pads disposed in adjacent island substrates among the plurality of island substrates, an upper substrate disposed above the lower substrate, and a viewing angle panel disposed above the upper substrate and including a plurality of structures configured to be deformed during stretching, and each sub pixel includes a display element area, a first wiring area, a second wiring area, and a transparent area.

### CROSS-REFERENCE TO RELATED APPLICATIONS

This application claims the benefit of and priority to Korean Patent Application No. 10-2024-0117844 filed on Aug. 30, 2024, in the Korean Intellectual Property Office, the entire contents of which are incorporated herein by reference for all purposes.

### BACKGROUND

### 1. Technical Field

The present disclosure relates to a device and particularly to, for example, without limitation, a stretchable display device.

### 2. Description of Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, recently, a stretchable display device which is manufactured by placing a flexible display unit and wiring line on a flexible substrate such as plastic which is a flexible material so as to be stretchable in a specific direction and changed in various forms is getting attention as a next generation display device.

The description of related art should not be considered prior art merely because it is mentioned in or associated with this section. The description of related art includes information that describes one or more aspects of the subject technology, and the description in this section does not limit the scope of the invention.

### SUMMARY

An aspect to be achieved by the present disclosure is to provide a stretchable display device which improves a degradation of a resolution due to the stretching of a stretchable display device.

Another aspect to be achieved by the present disclosure is to provide a stretchable display device which suppresses the damage or breakage due to the stretching of the stretchable display device.

Still another aspect to be achieved by the present disclosure is to provide a stretchable display device which improves a yellowish reflective visibility in a wiring area.

Aspects of the present disclosure are not limited to the above-mentioned aspects, and other aspects, which are not mentioned above, can be clearly understood by those skilled in the art from the following descriptions.

In order to achieve the aspects as described above, according to an aspect of the present disclosure, a stretchable display device includes a lower substrate, a plurality of pixels including a plurality of sub pixels, a plurality of island substrates disposed on the lower substrate and spaced apart from each other, each corresponding to a respective pixel, a plurality of connection lines which electrically connects pads disposed in the adjacent island substrates among the plurality of island substrates, an upper substrate disposed above the lower substrate, and a viewing angle panel disposed above the upper substrate and including a plurality of structures configured to be deformed during stretching. Each sub pixel may include a display element area, a first wiring area, a second wiring area, and a transparent area.

Other detailed matters of the example embodiments are included in the detailed description and the drawings.

According to one or more aspects of the present disclosure, a flexible viewing angle panel having a structure which is deformed during the stretching is disposed above the display panel to improve the degradation of the resolution during the stretching. Further, the flexible viewing angle panel suppresses exceeding of the tensile stress when the display panel is stretched to suppress the damage or breakage of the display panel due to the stretching.

According to one or more aspects of the present disclosure, a corresponding structure is disposed above the connection line of the line area to improve the yellowish reflective visibility due to the connection line.

The effects according to one or more aspects of the present disclosure are not limited to the contents described above, and more various effects are included in the present specification.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is an exploded perspective view of a stretchable display device according to example embodiments of the present disclosure;

FIG. 2 is an enlarged plan view of a stretchable display device according to a first example embodiment of the present disclosure;

FIG. 3 is a cross-sectional view taken along the line A-A′ of FIG. 2 according to a first example embodiment of the present disclosure;

FIG. 4 is a plan view of a viewing angle panel of a stretchable display device of FIG. 3 according to a first example embodiment of the present disclosure;

FIG. 5 is a cross-sectional view of a stretchable display device of FIG. 3 after being stretched according to a first example embodiment of the present disclosure;

FIG. 6 is a plan view of a viewing angle panel of FIG. 4 after being stretched according to a first example embodiment of the present disclosure;

FIG. 7 is a graph illustrating a luminance according to a viewing angle according to a first example embodiment of the present disclosure;

FIG. 8 is a cross-sectional view of a stretchable display device according to a second example embodiment of the present disclosure;

FIG. 9 is a plan view of a viewing angle panel of a stretchable display device of FIG. 8 according to a second example embodiment of the present disclosure;

FIG. 10 is a cross-sectional view of a stretchable display device of FIG. 8 after being stretched according to a second example embodiment of the present disclosure;

FIG. 11 is a plan view of a viewing angle panel of FIG. 9 after being stretched according to a second example embodiment of the present disclosure;

FIG. 12 is a plan view of a stretchable display device according to a third example embodiment of the present disclosure;

FIG. 13 is a cross-sectional view taken along the line B-B′ of FIG. 12 according to a third example embodiment of the present disclosure;

FIG. 14 is a plan view of a viewing angle panel of a stretchable display device of FIG. 13 according to a third example embodiment of the present disclosure;

FIG. 15 is a cross-sectional view of a stretchable display device of FIG. 13 after being stretched according to a third example embodiment of the present disclosure;

FIG. 16 is a plan view of a viewing angle panel of FIG. 14 after being stretched according to a third example embodiment of the present disclosure;

FIG. 17 is a plan view of a stretchable display device according to a fourth example embodiment of the present disclosure;

FIG. 18 is a cross-sectional view taken along C-C′ of FIG. 17 according to a fourth example embodiment of the present disclosure; and

FIG. 19 is a cross-sectional view of a stretchable display device of FIG. 17 after being stretched according to a fourth example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including”, “having”, and “consist of” used herein are generally intended to allow other components to be added unless the terms are used with the term “only”. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

Any implementation described herein as an “example” is not necessarily to be construed as preferred or advantageous over other implementations.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

In describing a temporal relationship, when the temporal order is described as, for example, “after”, “subsequent”, “next”, and “before”, a case that is not continuous may be included unless a more limiting term, such as “just”, “immediate(ly)”, or “direct(ly)” is used.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Also, when an element or layer is “connected”, “coupled”, or “adhered” to another element or layer denotes that the element or layer can not only be directly connected or adhered to the other element or layer, but also be indirectly connected or adhered to the other element or layer with one or more intervening elements or layers “disposed”, or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

Like reference numerals generally denote like elements throughout the specification.

A size and a thickness of each component illustrated in the drawing are illustrated for convenience of description, and the present disclosure is not limited to the size and the thickness of the component illustrated.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

The features of various embodiments of the present disclosure can be partially or entirely adhered to or combined with each other and can be interlocked and operated in technically various ways, and the embodiments can be carried out independently of or in association with each other.

Hereinafter, an example embodiment of the present disclosure will be described in detail with reference to the drawings.

A stretchable display device may be referred to as a display device which is capable of displaying images even though the display device is bent or stretched. The stretchable display device may have a high flexibility as compared with a general display device. Therefore, a shape of a stretchable display device may be freely changed in accordance with manipulation of a user to bend or stretch a stretchable display device. For example, when the user holds ends of the stretchable display device to pull the stretchable display device, the stretchable display device may be extended by the force of the user. Alternatively, when the user disposes the stretchable display device on a wall surface which is not flat, the stretchable display device may be disposed to be bent in accordance with the shape of the surface of the wall. Further, when a force applied by the user is removed, the stretchable display device may return to its original shape.

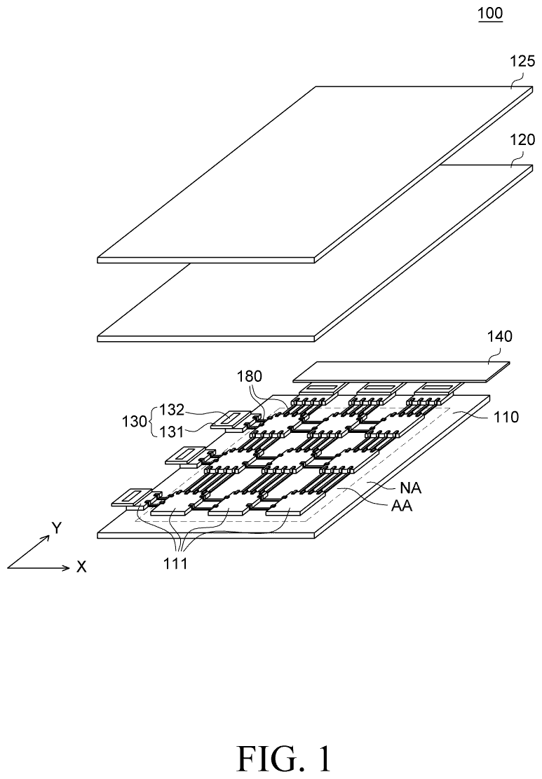

FIG. 1 is an exploded perspective view of a stretchable display device according to example embodiments of the present disclosure.

Referring to FIG. 1, the stretchable display device 100 may include a lower substrate 110, a plurality of island substrates 111, a connection line 180, a chip on film (COF) 130, a printed circuit board 140, an upper substrate 120, and a polarization layer 125.

For the convenience of description, in FIG. 1, a lower adhesive layer for attaching the lower substrate 110 and the upper substrate 120 is not illustrated.

The lower substrate 110 is a substrate which supports and protects several components of the stretchable display device 100. The lower substrate 110 which is a flexible substrate may be configured by an insulating material which is bendable or stretchable.

For example, the lower substrate 110 may be formed of a silicon rubber such as polydimethylsiloxane (PDMS) or an elastomer such as polyurethane (PU) or polytetrafluoroethylene (PTFE) and thus have a flexible property. However, the material of the lower substrate 110 is not limited thereto.

The lower substrate 110 is a flexible substrate so as to be reversibly expanded and contracted. Further, an elastic modulus of the lower substrate may be several MPa to several hundreds of MPa and a ductile breaking rate may be 100% or higher. For example, a thickness of the lower substrate 110 may be 10 μm to 1 mm, but is not limited thereto.

For example, the lower substrate 110 may have an active area AA and a non-active area NA enclosing the active area AA.

First, the active area AA is an area in which an image is displayed in the stretchable display device 100 and a display element and various driving elements for driving the display element may be disposed in the active area AA. The active area AA may include a plurality of pixels including a plurality of sub pixels. The plurality of pixels is disposed in the active area AA and may include a plurality of display elements. The plurality of sub pixels may be connected to various wiring lines, respectively. For example, each of the plurality of sub pixels may be connected to various wiring lines such as a gate line, a data line, a high potential power line, a low potential power line, and a reference voltage line.

The non-active area NA is an area adjacent to the active area AA. The non-active area NA is adjacent to the active area AA to enclose the active area AA. In the non-active area NA, no image is displayed and wiring lines and circuit units may be disposed. For example, in the non-active area NA, a plurality of pads is disposed and the pads may be connected to the plurality of sub pixels of the active areas AA, respectively.

The plurality of island substrates 111 may be disposed on the lower substrate 110. The plurality of island substrates 111 is rigid substrates and is spaced apart from each other to be disposed on the lower substrate 110. The plurality of island substrates 111 may be rigider than the lower substrate 110. That is, the lower substrate 110 may have a ductility relatively higher than the plurality of island substrates 111 and the plurality of island substrates 111 may have a rigidity relatively higher than the lower substrate 110.

The island substrate 111 is formed of a plastic material having a high rigidity and flexibility and for example, may be formed of polyimide (PI), polyacrylate, or polyacetate.

A modulus of the plurality of island substrates 111 may be higher than a modulus of the lower substrate 110. The modulus is an elastic modulus which represents a ratio being deformed by a stress with respect to a stress applied to the substrate. The relatively higher the modulus, the relatively higher the degree of hardness. Therefore, the plurality of island substrates 111 may be a plurality of rigid substrates which is rigider than the lower substrate 110. For example, the moduli of the plurality of island substrates 111 may be 1000 times higher than the modulus of the lower substrate 110, but is not limited thereto.

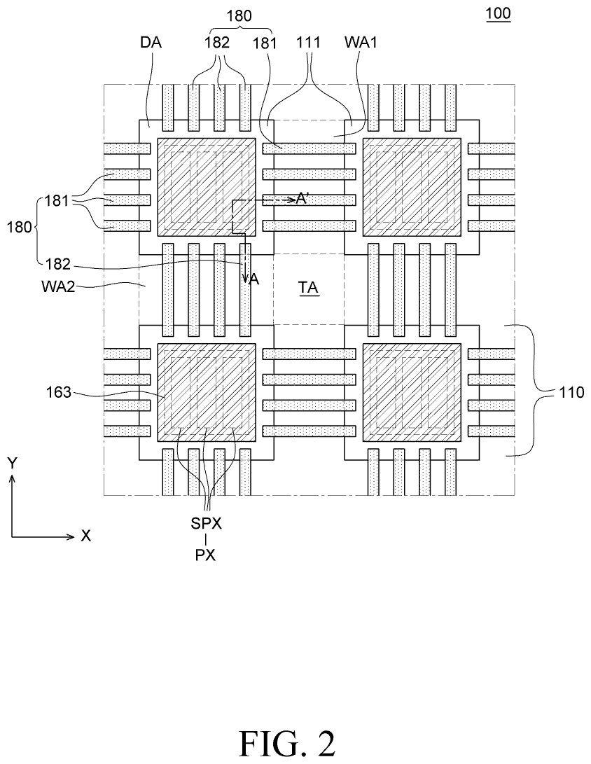

The connection line 180 may be disposed between the plurality of island substrates 111. For example, the connection line 180 is disposed between pads disposed above the plurality of island substrates 111 to electrically connect the pads to each other. The connection line 180 will be described below in more detail with reference to FIG. 2.

The COF 130 is a film on which various components, such as a driving IC 132, are disposed on a base film 131 having a malleability and supplies signals to the plurality of sub pixels of the active area AA. The COF 130 may be bonded to the plurality of pads disposed in the non-active area NA and supply a power voltage, a data voltage, and a gate voltage to the plurality of sub pixels of the active area AA through the pads. The COF 130 includes the base film 131 and a driving IC 132. Further, various components may be additionally disposed thereon.

The base film 131 is a layer which supports the driving IC 132 of the COF 130. The base film 131 may be formed of an insulating material, and for example, may be formed of an insulating material having a flexibility.

The driving IC 132 is a component which processes data for displaying images and a driving signal for processing the image.

In FIG. 1, even though it is illustrated that the driving IC 132 is mounted by the COF 130 technique, it is not limited thereto and the driving IC 132 may be mounted by a technique, such as chip on glass (COG) or tape carrier package (TCP).

A control unit such as an IC chip or a circuit unit may be mounted on the printed circuit board 140. Further, on the printed circuit board 140, a memory or a processor may be mounted. The printed circuit board 140 is a component which transmits a signal for driving the display element from the control unit to the display element.

The printed circuit board 140 is connected to the COF 130 to be electrically connected to each of the plurality of sub pixels of the plurality of island substrates 111.

The upper substrate 120 overlaps the lower substrate 110 to protect various components of the stretchable display device 100. The upper substrate 120 which is a flexible substrate may be configured by an insulating material which is bendable or stretchable. For example, the upper substrate 120 may be formed of a flexible material and formed of the same material as the lower substrate 110, but is not limited thereto.

Further, the polarization layer 125 is a configuration which suppresses external light reflection of the stretchable display device 100 and overlaps the upper substrate 120 to be disposed on the upper substrate 120. However, the polarization layer 125 is not limited thereto and may be disposed below the upper substrate 120 or omitted depending on the configuration of the stretchable display device 100.

Hereinafter, the stretchable display device 100 according to the example embodiments of the present disclosure will be described in more detail with reference to FIGS. 2 to 6.

FIG. 2 is an enlarged plan view of a stretchable display device according to a first example embodiment of the present disclosure.

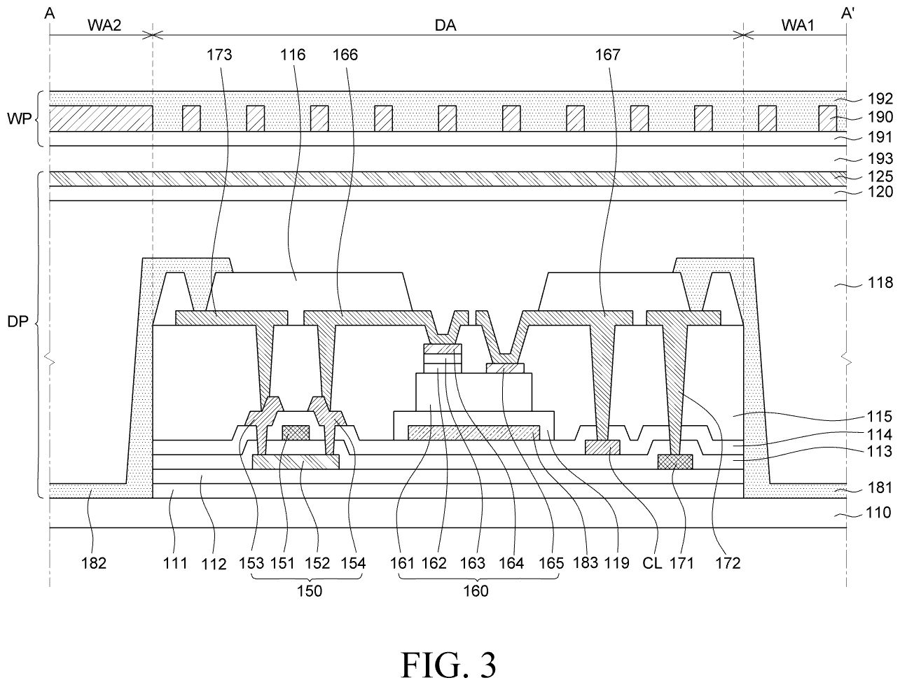

FIG. 3 is a cross-sectional view taken along the line A-A′ of FIG. 2.

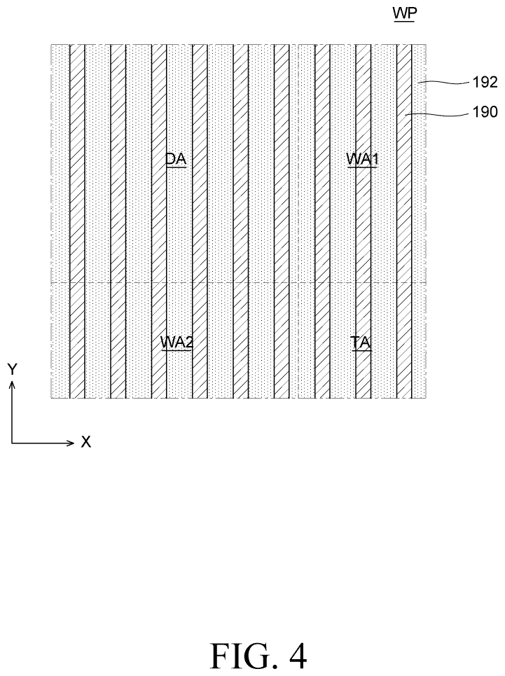

FIG. 4 is a plan view of a viewing angle panel of a stretchable display device of FIG. 3.

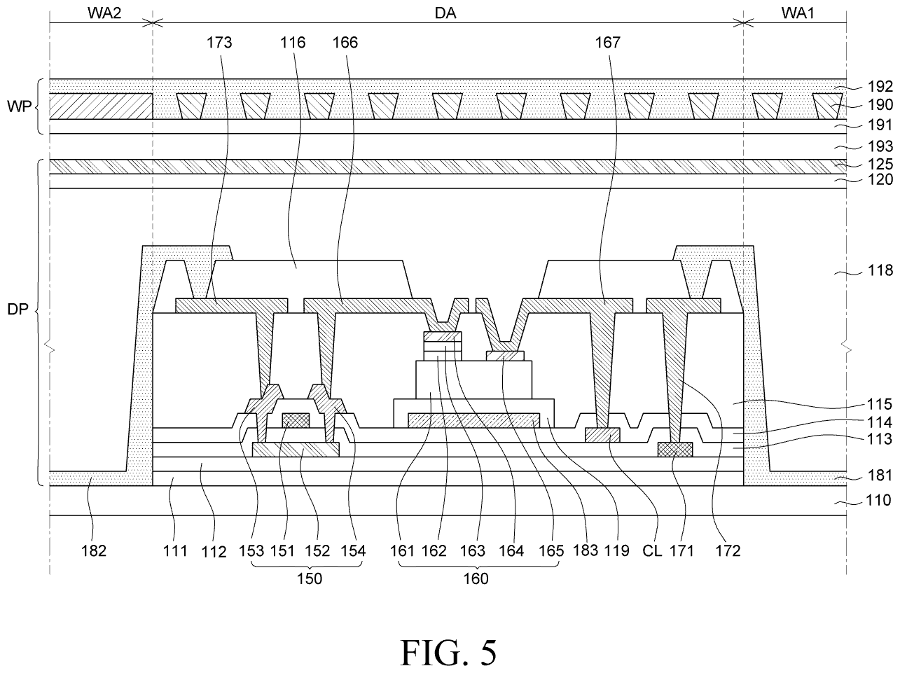

FIG. 5 is a cross-sectional view of a stretchable display device of FIG. 3 after being stretched.

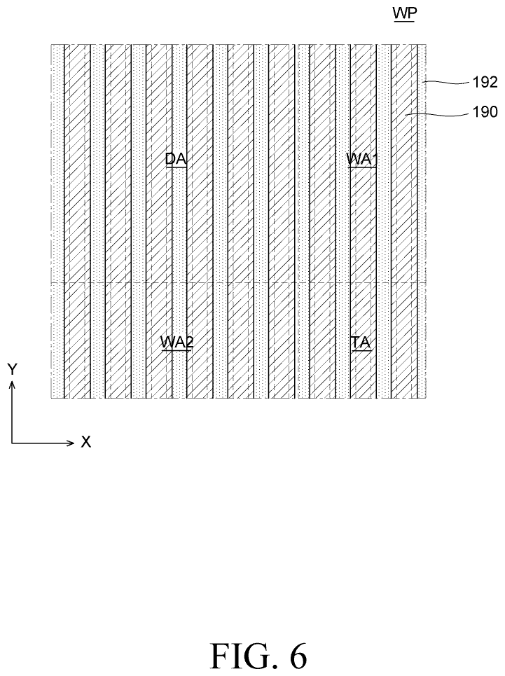

FIG. 6 is a plan view of a viewing angle panel of FIG. 4 after being stretched.

FIGS. 2 to 6 illustrate a stretchable display device of a first example embodiment of the present disclosure when the stretching is performed in a horizontal direction (that is, an X-axis direction) as an example. In this case, the structure may be disposed in a direction substantially perpendicular to the stretching direction (that is, a Y-axis direction).

FIG. 4 is a schematic plan view of a viewing angle panel corresponding to one sub pixel in the stretchable display device of FIG. 3.

FIGS. 5 and 6 are a cross-sectional view of a stretchable display device after being stretched when the stretching is performed in the horizontal direction (that is, the X-axis direction) and a plan view of a viewing angle panel.

For the convenience of description, the description will be made also with reference to FIG. 1.

Referring to FIGS. 2 to 6, a plurality of island substrates 111 may be disposed on the lower substrate 110. The plurality of island substrates 111 is spaced apart from each other to be disposed on the lower substrate 110. For example, as illustrated in FIGS. 1 and 2, the plurality of island substrates 111 may be disposed on the lower substrate 110 in a matrix, but is not limited thereto.

For example, the lower substrate 110 may have an active area AA and a non-active area NA enclosing the active area AA.

For example, the active area AA includes a plurality of pixels PX including a plurality of sub pixels SPX and one sub pixel SPX may include a display element area DA, a first wiring area WA1, a second wiring area WA2, and a transparent area TA.

In the display element area DA, a display element and various driving elements for driving the display element may be disposed.

For example, the display element may be a micro LED 160, but is not limited thereto and may be an organic light emitting diode or a liquid crystal display element including an anode, an organic emission layer, and a cathode.

For example, the driving element may be a transistor 150, but the present disclosure is not limited thereto.

At this time, the first wiring area WA1 is disposed on one side of the display element area DA and may be disposed between the display element areas DA adjacent in the X-axis direction.

For example, the first connection line 181 may be disposed in the first wiring area WA1. The first connection line 181 refers to a wiring line extending in the X-axis direction, among the connection lines 180.

The first connection line 181 may connect pads above two island substrates 111 which are disposed in parallel, among pads above the plurality of island substrates 111 adjacent to each other in the X-axis direction. The first connection line 181 may serve as a gate line or a low potential power line, but is not limited thereto.

Further, the second wiring area WA2 is disposed on the other side of the display element area DA and is disposed between the display element areas DA adjacent in the Y-axis direction.

For example, the second connection line 182 may be disposed in the second wiring area WA2. The second connection line 182 refers to a wiring line extending in the Y-axis direction, among the connection lines 180.

The second connection line 182 may connect pads above two island substrates 111 which are disposed in parallel, among pads above the plurality of island substrates 111 adjacent to each other in the Y-axis direction. The second connection line 182 may serve as a data line, a high potential power line, or a reference voltage line, but is not limited thereto.

Further, the transparent area TA may be disposed between the first wiring areas WA1 adjacent in the Y-axis direction and between the second wiring area WA2 adjacent in the X-axis direction. In the meantime, in an area other than an area of the first wiring area WA1 and the second wiring area WA2 in which the first connection line 181 and the second connection line 182 are disposed, opaque components are not disposed so that it is also considered as a transparent area.

In the transparent area TA, opaque components are not provided and the lower substrate 110 formed of elastomer is disposed so that the transparent area may be translucent.

The plurality of island substrates 111 may be disposed in the display element area DA.

A buffer layer 112 may be disposed on the plurality of island substrates 111. For example, the buffer layer 112 may be formed on the plurality of island substrates 111 to protect various components of the stretchable display device 100 from infiltration of moisture H2O and oxygen O2 from the outside of the lower substrate 110 and the plurality of island substrates 111.

At this time, the buffer layer 112 may be configured by an insulating material and for example, configured by a single layer or a double layer of an inorganic layer formed of silicon nitride (SiNx), silicon oxide (SiOx), and silicon oxynitride (SiON). However, the buffer layer 112 may be omitted depending on a structure or a characteristic of the stretchable display device 100.

The buffer layer 112 may be formed only in an area overlapping the plurality of island substrates 111. As described above, the buffer layer 112 may be formed of an inorganic material so that the buffer layer may be easily cracked or damaged during a process of stretching the stretchable display device 100. Therefore, the buffer layer 112 is not disposed in an area between the plurality of island substrates 111, but is patterned to have a shape of the plurality of island substrates 111 to be formed only above the plurality of island substrates 111. Therefore, in the stretchable display device 100 according to the first example embodiment of the present disclosure, the buffer layer 112 is disposed only in an area overlapping the plurality of island substrates 111 which is rigid substrates. Therefore, even though the stretchable display device 100 is bent or stretched to be deformed, the damage of the buffer layer 112 may be suppressed.

The gate pad 171 may be disposed on the buffer layer 112, but is not limited thereto. The gate pad 171 is a pad which transmits a gate signal to the plurality of sub pixels SPX. The gate pad 171 may be formed of the same material as the gate electrode 151, but is not limited thereto.

A transistor 150 including a gate electrode 151, an active layer 152, a source electrode 153, and a drain electrode 154 may be formed above the buffer layer 112.

The transistor 150 may be disposed in the display element area DA.

For example, the active layer 152 is disposed on the buffer layer 112 and a gate insulating layer 113 may be disposed on the active layer 152 to insulate the active layer 152 and the gate electrode 151 from each other.

The common line CL may be disposed on the gate insulating layer 113.

The common line CL is a wiring line which applies a common voltage to the plurality of sub pixels SPX. The common line CL may be formed of the same material as the source electrode 153 and the drain electrode 154 of the transistor 150, but is not limited thereto.

Further, an interlayer insulating layer 114 may be disposed on the gate insulating layer 113 to insulate the gate electrode 151 and the source electrode 153 from the drain electrode 154. Further, the source electrode 153 and the drain electrode 154 which are in contact with the active layer 152 may be disposed on the interlayer insulating layer 114.

The gate insulating layer 113 and the interlayer insulating layer 114 are patterned to be disposed only in an area overlapping the plurality of island substrates 111. The gate insulating layer 113 and the interlayer insulating layer 114 are also formed of the inorganic material, similarly to the buffer layer 112, so that the gate insulating layer 113 and the interlayer insulating layer 114 may also be easily cracked to be damaged during the process of stretching the stretchable display device 100. Therefore, the gate insulating layer 113 and the interlayer insulating layer 114 are not disposed in an area between the plurality of island substrates 111, but are patterned to have a shape of the plurality of island substrates 111 to be disposed only above the plurality of island substrates 111.

In FIG. 3, even though among various transistors which may be included in the stretchable display device 100, only a driving transistor is illustrated for the convenience of description, but is not limited thereto and a switching transistor or a capacitor may also be included in the display device. Further, in this specification, even though it is described that the transistor 150 has a coplanar structure, various transistors such as a staggered structure may also be used. Further, the reflective layer 183 may be disposed on the interlayer insulating layer 114.

The reflective layer 183 is a layer which reflects light which is emitted to be directed to the lower substrate 110 among light emitted from the LED 160 onto an upper portion of the stretchable display device 100 to output the light to the outside. The reflective layer 183 may be formed of a metal material having a high reflectivity.

An adhesive layer 119 may be disposed on the reflective layer 183 to cover the reflective layer 183.

The adhesive layer 119 is a layer for bonding the LED 160 onto the reflective layer 183 and may also insulate the reflective layer 183 formed of a metal material from the LED 160. For example, the adhesive layer 119 may be formed of a thermal curing material or a photo curing material, but is not limited thereto. In FIG. 3, even though it is illustrated that the adhesive layer 119 is disposed so as to cover only the reflective layer 183, but the placement position of the adhesive layer 119 is not limited thereto.

The LED 160 may be disposed above the adhesive layer 119. The LED 160 may be disposed to overlap the reflective layer 183.

The LED 160 may be disposed in the display element area DA.

The LED 160 may include an n-type layer 161, an active layer 162, a p-type layer 163, an n-electrode 165, and a p-electrode 164. Hereinafter, it is described that a lateral LED 160 is used as the LED 160 as an example, but it is not limited thereto.

For example, the n-type layer 161 of the LED 160 may be disposed on the adhesive layer 119 to overlap the reflective layer 183. The n-type layer 161 may be formed by injecting an n-type impurity into gallium nitride having excellent crystallinity. The active layer 162 may be disposed on the n-type layer 161. The active layer 162 is an emission layer which emits light in the LED 160 and may be formed of a nitride semiconductor, for example, indium gallium nitride. The p-type layer 163 may be disposed on the active layer 162. The p-type layer 163 may be formed by injecting a p-type impurity into gallium nitride. However, constitution materials of the n-type layer 161, the active layer 162, and the p-type layer 163 are not limited thereto.

The p-electrode 164 may be disposed on the p-type layer 163 of the LED 160. The n-electrode 165 may be disposed on the n-type layer 161 of the LED 160. The n-electrode 165 may be disposed to be spaced apart from the p-electrode 164. For example, the LED 160 is manufactured by sequentially laminating the n-type layer 161, the active layer 162, and the p-type layer 163, etching a predetermined part of the active layer 162 and the p-type layer 163, and forming the n-electrode 165 and the p-electrode 164. In this case, the predetermined part which is a space for separating the n-electrode 165 and the p-electrode 164 from each other may be etched to expose a part of the n-type layer 161. That is, the surfaces of the LED 160 to dispose the n-electrode 165 and the p-electrode 164 are not flat surfaces and have different heights. Therefore, the p-electrode 164 is disposed on the p-type layer 163 and the n-electrode 165 is disposed on the n-type layer 161 and the p-electrode 164 and the n-electrode 165 may be disposed at different levels to be spaced apart from each other.

Further, the n-electrode 165 may be disposed to be closer to the reflective layer 183 than the p-electrode 164. Further, the n-electrode 165 and the p-electrode 164 may be formed of a conductive material and for example, formed of a transparent conductive oxide. Further, the n-electrode 165 and the p-electrode 164 may be formed of the same material, but are not limited thereto.

The planarization layer 115 may be disposed above the interlayer insulating layer 114 and the adhesive layer 119.

The planarization layer 115 planarizes an upper surface of the transistor 150. The planarization layer 115 may be disposed in an area excluding an area where the LED 160 is disposed while planarizing the upper surface of the planarization layer 115. The planarization layer 115 may be configured by two or more layers.

In some example embodiments, an additional insulating layer may be formed between the transistor 150 and the planarization layer 115. That is, the additional insulating layer which covers the transistor 150 may be disposed to protect the transistor 150 from the permeation of the moisture and oxygen. The additional insulating layer may be formed of an inorganic material and may be formed by a single layer and a double layer and the additional insulating layer may be a passivation layer, but the present disclosure is not limited thereto.

A first electrode 166 and a second electrode 167 may be disposed on the planarization layer 115. The first electrode 166 is an electrode which electrically connects the transistor 150 and the LED 160.

The first electrode 166 may be connected to the p-electrode 164 of the LED 160 through a contact hole formed in the planarization layer 115. Further, the first electrode 166 may be connected to the drain electrode 154 of the transistor 150 through contact holes formed in the planarization layer 115 and the interlayer insulating layer 114. However, the first electrode 166 is not limited thereto, but may be connected to the source electrode 153 of the transistor 150 depending on the type of the transistor 150. The p-electrode 164 of the LED 160 and the drain electrode 154 of the transistor 150 may be electrically connected to each other by the first electrode 166.

Further, the second electrode 167 is an electrode which electrically connects the LED 160 and the common line CL. For example, the second electrode 167 is connected to the common line CL through the contact holes formed in the planarization layer 115 and the interlayer insulating layer 114 and may be connected to the n-electrode 165 of the LED 160 through the contact hole formed in the planarization layer 115. Accordingly, the common line CL and the n-electrode 165 of the LED 160 may be electrically connected.

When the stretchable display device 100 is turned on, different levels of voltages may be applied to the drain electrode 154 and the common line CL of the transistor 150. A voltage applied to the drain electrode 154 of the transistor 150 is applied to the first electrode 166 and a common voltage may be applied to the second electrode 167. Different levels of voltages may be applied to the p-electrode 164 and the n-electrode 165 through the first electrode 166 and the second electrode 167 so that the LED 160 may emit light.

In FIG. 3, it is illustrated that the transistor 150 is electrically connected to the p-electrode 164 and the common line CL is electrically connected to the n-electrode 165 as an example, but the present disclosure is not limited thereto. Therefore, the transistor 150 is electrically connected to the n-electrode 165 and the common line CL may be electrically connected to the p-electrode 164.

The data pad 173 and the connection pad 172 may be disposed above the planarization layer 115.

The data pad 173 may transmit a data signal from the connection line 180 which serves as the data line to the plurality of sub pixels SPX. The data pad 173 may be connected to the source electrode 153 of the transistor 150 through a contact hole formed in the planarization layer 115.

Further, the connection pad 172 transmits a gate signal from the connection line 180 which serves as the gate line to the plurality of sub pixels SPX. The connection pad 172 is connected to the gate pad 171 through the contact hole formed in the planarization layer 115 and the interlayer insulating layer 114 and may transmit the gate signal to the gate pad 171. The connection pad 172 may be formed of the same material as the data pad 173, but is not limited thereto.

A bank 116 may be disposed on the planarization layer 115, the first electrode 166, and the second electrode 167. The bank 116 is disposed so as to overlap the end of the reflective layer 183 and a part of the reflective layer 183 which does not overlap the bank 116 may be defined as an emission area. The bank 116 may be formed of an organic insulating material and may be formed of the same material as the planarization layer 115. Further, the bank 116 may be configured to include a black material to suppress light emitted from the light emitting diode (LED) 160 from being transmitted to the adjacent sub pixels SPX to cause the color mixture. For example, the bank 116 may be formed of polyimide, acrylic-based resin, or benzocyclobutene (BCB)-based resin, but is not limited thereto.

The stretchable display device 100 according to the first example embodiment of the present disclosure may include an LED 160. At this time, since the LED 160 is formed of an inorganic material, rather than an organic material, reliability is excellent so that a lifespan thereof is longer than that of the liquid crystal display element or the organic light emitting diode. Further, the LED 160 has a fast lighting speed, low power consumption, and excellent stability due to high impact resistance and has excellent emission efficiency to display images having high luminance so that it is suitable for a very large screen. Specifically, the LED 160 is formed of an inorganic material, rather than an organic material so that it may not use an encapsulation layer which is required when an organic light emitting diode is used. Therefore, the encapsulation layer which is easily cracked or damaged during a process of stretching the stretchable display device 100 may be omitted. Accordingly, in the stretchable display device 100 according to the first example embodiment of the present disclosure, the LED 160 is used as a display element so that the encapsulation layer which may be easily damaged when the stretchable display device 100 is bent or stretched to be deformed may be omitted. Further, the LED 160 is formed of an inorganic material, rather than the organic material so that the display element of the stretchable display device 100 according to the first example embodiment of the present disclosure may be protected from the moisture or oxygen and have excellent reliability.

The stretchable display device 100 of the first example embodiment of the present disclosure has a structure in which a plurality of island substrates 111 having a relatively rigidity is spaced apart from each other to be disposed on the lower substrate 110 having relatively malleability. Therefore, in the stretchable display device 100 according to the first example embodiment of the present disclosure, when the user stretches or bends the stretchable display device 100, the stretchable display device 100 is more easily deformed. Further, when the stretchable display device 100 is deformed, the damages of components of the stretchable display device 100 due to the deformation may be minimized or reduced.

The connection line 180 refers to a wiring line which electrically connects pads above the plurality of island substrates 111. The connection line 180 may include a first connection line 181 and a second connection line 182. The first connection line 181 refers to a wiring line extending in an X-axis direction among the connection lines 180 and the second connection line 182 refers to a wiring line extending in a Y-axis direction among the connection lines 180.

In the case of a general stretchable display device, various wiring lines such as a plurality of gate lines and a plurality of data lines extend between the plurality of sub pixels and a plurality of sub pixels is connected to one signal line. Therefore, in the general stretchable display device, various wiring lines such as a gate line, a data line, a high potential power source line, and a reference voltage line extend from one side to the other side of the stretchable display device without being disconnected on the substrate.

In contrast, in the stretchable display device 100 according to the first example embodiment of the present disclosure, various wiring lines such as the gate line, the data line, the high potential power source line, and the reference voltage line formed of a metal material may be disposed only above the plurality of island substrates 111. That is, in the stretchable display device 100 according to the first example embodiment of the present disclosure, various wiring lines formed of a metal material are disposed only above the plurality of island substrates 111, but may be not in contact with the lower substrate 110. Therefore, various wiring lines may be patterned so as to correspond to the plurality of island substrates 111 to be discontinuously disposed.

In the stretchable display device 100 according to the first example embodiment of the present disclosure, in order to connect the discontinuous wiring lines, pads above two adjacent island substrates 111 may be connected by the connection line 180. That is, the connection line 180 may electrically connect pads above two adjacent island substrates 111. Therefore, the stretchable display device 100 of the present disclosure may include a plurality of connection lines 180 to electrically connect various wiring lines such as the gate line, the data line, the high potential power source line, and the reference voltage line to each other between the plurality of island substrates 111. For example, the gate line may be disposed above the plurality of island substrates 111 disposed to be adjacent to each other in the X-axis direction and the gate pad 171 may be disposed on both ends of the gate line. At this time, the plurality of gate pads 171 above the plurality of island substrates 111 adjacent to each other in the X-axis direction may be connected to each other by the connection line 180 which serves as a gate line. Therefore, the gate line disposed above the plurality of island substrates 111 and the connection line 180 disposed above the lower substrate 110 may serve as one gate line. That is, all various wiring lines which may be included in the stretchable display device 100, such as the data line, the high potential power line, and the reference voltage line may also serve as one wiring line by the connection line 180 as described above.

The first connection line 181 may connect pads above two island substrates 111 which are disposed in parallel, among pads above the plurality of island substrates 111 adjacent to each other in the X-axis direction. The first connection line 181 may serve as a gate line or a low potential power line, but is not limited thereto. For example, the first connection line 181 may serve as a gate line and electrically connect gate pads 171 above two island substrates 111 disposed in parallel in the X-axis direction, through the contact hole formed in the bank 116. Therefore, as described above, the gate pads 171 above the plurality of island substrates 111 disposed in the X-axis direction may be connected by the first connection line 181 serving as a gate line and transmit one gate signal.

The first connection line 181 may be disposed in the first wiring area WA1.

The second connection line 182 may connect pads above two island substrates 111 which are disposed in parallel, among pads above the plurality of island substrates 111 adjacent to each other in the Y-axis direction. The second connection line 182 may serve as a data line, a high potential power line, or a reference voltage line, but is not limited thereto. For example, the second connection line 182 may serve as a data line and electrically connect data pads 173 above two island substrates 111 disposed in parallel in the Y-axis direction, through the contact hole formed in the bank 116. Therefore, as described above, the data pads 173 above the plurality of island substrates 111 disposed in the Y-axis direction may be connected by the plurality of second connection lines 182 serving as a data line and transmit one data signal.

The second connection line 182 may be disposed in the second wiring area WA2.

The connection line 180 may include a base polymer and conductive particles. For example, the first connection line 181 includes a base polymer and conductive particles and the second connection line 182 may include a base polymer and conductive particles.

The first connection line 181 may be formed to extend to a top surface of the lower substrate 110 while being in contact with a top surface and a side surface of the bank 116 disposed above the island substrate 111, and side surfaces of the planarization layer 115, the interlayer insulating layer 114, the buffer layer 112, and the plurality of island substrates 111. Therefore, the first connection line 181 is in contact with the top surface of the lower substrate 110, is in contact with the side surfaces of the adjacent island substrates 111, and may be in contact with the side surfaces of the buffer layer 112, the gate insulating layer 113, the interlayer insulating layer 114, the planarization layer 115, and the bank 116 disposed above the adjacent island substrates 111. Further, the first connection line 181 may be in contact with the connection pad 172 disposed in the adjacent island substrate 111, but is not limited thereto.

At this time, the base polymer of the first connection line 181 may be configured by a bendable or stretchable insulating material, similarly to the lower substrate 110. The base polymer may include, for example, styrene butadiene styrene (SBS), but is not limited thereto. Therefore, when the stretchable display device 100 is bent or stretched, the base polymer may not be damaged. The base polymer may be formed by coating an upper portion of the lower substrate 110 or the island substrate 111 with a material which configures the base polymer or applying the material which configures the base polymer using a slit.

The conductive particles of the first connection line 181 may be dispersed in the base polymer. At this time, the first connection line 181 may include conductive particles which are dispersed in the base polymer with a predetermined concentration. The first connection line 181 may be formed by uniformly agitating the conductive particles in the base polymer and then coating and curing the base polymer in which the conductive particles are dispersed, above the lower substrate 110 and the island substrate 111, but is not limited thereto. The conductive particles may include at least one of silver (Ag), gold (Au), and carbon, but are not limited thereto.

The conductive particles dispersed in the base polymer of the first connection line 181 may form a conductive path which electrically connects the connection pads 172 disposed on the island substrates 111 adjacent to each other. Further, the conductive particles may form a conductive path by electrically connecting a gate pad 171 disposed on an island substrate 111 disposed at an outermost edge among the plurality of island substrates 111 and the pad disposed in the non-active area NA.

The base polymer of the first connection line 181 and the conductive particles dispersed in the base polymer may linearly connect the pads disposed on the adjacent island substrates 111. To this end, during the manufacturing process, the base polymer may be formed to have a linear shape which connects the pads disposed on the plurality of island substrates 111. Therefore, the conductive path formed by the conductive particles dispersed in the base polymer may also have a linear shape. However, the process of forming the base polymer and the conductive particles of the first connection line 181 and the shape thereof are not limited thereto.

The second connection line 182 may be formed to extend to the top surface of the lower substrate 110 while being in contact with the top surface and the side surface of the bank 116 disposed above the island substrate 111, and the side surfaces of the planarization layer 115, the interlayer insulating layer 114, the buffer layer 112, and the plurality of island substrates 111. Therefore, the second connection line 182 is in contact with the top surface of the lower substrate 110, is in contact with the side surfaces of the adjacent island substrates 111, and is in contact with the side surfaces of the buffer layer 112, the gate insulating layer 113, the interlayer insulating layer 114, the planarization layer 115, and the bank 116 disposed above the adjacent island substrates 111. Further, the second connection line 182 may be in contact with the data pad 173 disposed in the adjacent island substrate 111, but is not limited thereto.

Further, similarly to the lower substrate 110, the base polymer of the second connection line 182 may be configured of a bendable or stretchable insulating material and may be the same material as the base polymer of the first connection line 181. The base polymer may include for example, SBS, but is not limited thereto.

Further, the conductive particles of the second connection line 182 may be dispersed in the base polymer. For example, the second connection line 182 may include conductive particles which are dispersed in the base polymer at a predetermined concentration. The concentration of the conductive particles dispersed in the upper portion of the base polymer of the second connection line 182 may be substantially the same as the concentration of the conductive particles dispersed in the lower portion of the base polymer. Further, the manufacturing process of the second connection line 182 may be the same as the manufacturing process of the first connection line 181 and the manufacturing processes may be simultaneously performed.

The conductive particles dispersed in the base polymer of the second connection line 182 may form a conductive path which electrically connects the data pad 173 disposed on the island substrates 111 adjacent to each other. Further, a data pad 173 disposed on an island substrate 111 disposed at an outermost edge among the plurality of island substrates 111 and the pad disposed in the non-active area NA are electrically connected to form a conductive path.

The base polymer of the second connection line 182 and the conductive particles dispersed in the base polymer may linearly connect the pads disposed on the adjacent island substrates 111. To this end, during the manufacturing process, the base polymer may be formed to have a linear shape which connects the pads disposed on the plurality of island substrates 111. Therefore, the conductive path formed by the conductive particles dispersed in the base polymer may also have a linear shape. However, the process of forming the base polymer and the conductive particles of the second connection line 182 and the shape thereof are not limited thereto.

In some example embodiments, the conductive particles dispersed in the base polymer of the connection line 180 may be disposed to be dispersed in the base polymer with a concentration gradient.

For example, the concentration of the conductive particles is reduced from the upper portion of the base polymer to the lower portion and thus, the conductivity by the conductive particles may be the largest in the upper portion of the base polymer. At this time, specifically, the conductive particles may be injected into the base polymer using an ink printing process which uses a conductive precursor to be dispersed on a top surface of the base polymer.

In the meantime, during the process of injecting the conductive particles in the base polymer, the polymer is swelled several times so that the conductive particles may be infiltrated into an empty space of the base polymer. As described above, when the base polymer in which the conductive particles are injected is dipped in a reducing material or is reduced using a vapor, the connection line 180 may be formed.

Therefore, in an infiltration area above the base polymer, a concentration of the conductive particles may be high enough to form the conductive path.

A thickness of the infiltration area where the conductive particles are dispersed in the upper portion of the base polymer at a high concentration may vary depending on a time when the conductive particles are injected onto the top surface of the base polymer and the strength. For example, the more the time or the strength that the conductive particles are injected onto the top surface of the base polymer, the larger the thickness of the infiltration area. Further, the conductive particles may be in contact with each other in the upper portion of the base polymer so that the conductive path is formed by the conductive particles which are in contact with each other to transmit an electrical signal.

Further, in some example embodiments, the base polymer of the connection line 180 may be formed above the lower substrate 110 between the adjacent island substrates 111 as a single layer. Specifically, unlike that illustrated in FIG. 2, the base polymer may be disposed to be in contact with the lower substrate 110 in an area between the island substrates 111 which are the most adjacent to each other in the X-axis direction as a single layer. The base polymer may be formed to overlap all the plurality of pads formed in parallel on one top base of one island substrate 111. Further, the conductive particles may be formed individually so as to correspond to the plurality of pads while forming a plurality of conductive paths on the base polymer disposed as one layer. Therefore, the conductive path formed by the conductive particles may linearly connect the pads disposed on the island substrates 111 which are adjacent to each other. For example, the conductive particles may be injected on the top surface of the base polymer disposed between the plurality of island substrates 111 as one layer to form four conductive paths.

In some example embodiments, the base polymer of the connection line 180 may be disposed in an entire area excluding an area where the plurality of island substrates 111 is disposed. The base polymer may be disposed as single layer to be in contact with the lower substrate 110 in an area of the lower substrate 110 excluding an area which overlaps a plurality of rigid substrates, that is, the plurality of island substrates 111. Therefore, the area of the lower substrate 110 excluding the area which overlaps the plurality of island substrates 111 may be covered by the base polymer. The base polymer may be in contact with the pads of the plurality of island substrates 111 so that a part of the base polymer may be disposed so as to cover the edge of the plurality of island substrates 111. Further, the conductive particles may form a conductive path which connects pads on the plurality of island substrates 111 adjacent to each other on the base polymer.

When the base polymer is disposed as a single layer in an entire area excluding the area where the plurality of island substrates 111 is disposed above the lower substrate 110, the base polymer may be formed to apply the entire area of the lower substrate 110 excluding an area where the plurality of island substrates 111 is disposed. Therefore, a separate process of patterning the base polymer may not be necessary. Therefore, the manufacturing process of the base polymer and the connection line may be simplified and the process cost and time may be reduced.

Since the base polymer is disposed as a single layer in the entire area excluding an area where the plurality of island substrates 111 is disposed above the lower substrate 110, a force applied when the stretchable display device 100 is bent or stretched may be dispersed. Further, in some example embodiments, the top surface of the base polymer of the connection line 180 may be flat.

For example, unlike that illustrated in FIG. 3, the top surface of the base polymer of the connection line 180, such as the gate line and the data line may be higher than the top surface of the planarization layer 115 above the plurality of island substrates 111. The top surface of the base polymer may be higher than the top surface of the bank 116 above the plurality of island substrates 111. Therefore, in the base polymer of the connection line 180, a height of a top surface of a portion overlapping the plurality of island substrates 111 may be equal to a height of a top surface of an area disposed between the plurality of island substrates 111. Therefore, the top surface of the connection line 180 may be flat. Accordingly, the top surfaces of the conductive particles dispersed above the base polymer may have a linear shape without having a curvature on the cross-section view.

There may be a step between the upper surface of the bank 116 and the upper surface of the lower substrate 110 due to various components above the plurality of island substrates 111 which is disposed to be spaced apart from each other on the lower substrate 110. In this case, the base polymer may be cut off by the step of the top surface of the base polymer so that an electrical path between the pads disposed in the adjacent island substrates 111 may be blocked and a defective rate of the stretchable display device may be increased.

In this case, when the upper surface of the base polymer is flat, a step between the top surface of the elements disposed on the plurality of island substrates 111 and the top surface of the lower substrate 110 on which the plurality of island substrates 111 is not disposed may be removed. Therefore, even though the stretchable display device 100 is bent or stretched, the cut-off of the connection line 180 including the base polymer and the conductive particles due to the step may be avoided. Further, the top surface of the base polymer becomes flat so that the damage of the connection line 180 during the process of manufacturing the stretchable display device 100 may be minimized or reduced.

The upper substrate 120, the polarization layer 125, and an upper adhesive layer 118 may be disposed above the lower substrate 110 configured as described above.

The upper substrate 120 is a substrate which supports various components disposed below the upper substrate 120. The upper substrate 120 which is a flexible substrate may be configured by an insulating material which is bendable or stretchable. The upper substrate 120 is a flexible substrate so as to be reversibly expanded and contracted. Further, an elastic modulus may be several MPa to several hundreds of MPa and a ductile breaking rate may be 100% or higher.

A thickness of the upper substrate 120 may be 10 μm to 1 mm, but is not limited thereto.

For example, the upper substrate 120 may be formed of the same material as the lower substrate 110, and for example, may be formed of a silicon rubber such as polydimethylsiloxane (PDMS) or an elastomer such as polyurethane (PU) or polytetrafluoroethylene (PTFE) and thus have a flexible property. However, the material of the upper substrate 120 is not limited thereto.

The upper substrate 120 may be formed as a film type. A pressure is applied to the upper substrate 120 and the lower substrate 110 from the upper portion or the lower portion so that the upper substrate 120 and the lower substrate 110 may be bonded by an upper adhesive layer 118 disposed below the upper substrate 120. However, the present disclosure is not limited thereto and the upper adhesive layer 118 may be omitted in some example embodiments. Further, the upper substrate 120 may be formed by a coating method, rather than the film type, and in this case, the upper adhesive layer 118 may be omitted.

The polarization layer 125 may be disposed on the upper substrate 120. At this time, the polarization layer 125 may polarize light incident from the outside of the stretchable display device 100. The polarized light which passes through the polarization layer 125 to be incident into the stretchable display device 100 may be reflected in the stretchable display device 100 so that a phase may be shifted. At this time, the light with a shifted phase may not pass through the polarization layer 125. Therefore, light which is incident into the stretchable display device 100 from the outside of the stretchable display device 100 is not released to the outside of the stretchable display device 100 so that the external light reflection of the stretchable display device 100 may be reduced.

As described above, the stretchable display device needs to be easily bendable or stretchable so that a modulus is small. Therefore, a substrate having a high malleability may be used therefor. At this time, the substrate may be manufactured with a flexible material having a small modulus, such as polydimethylsiloxane (PDMS). When the material is used as a lower substrate on which the display element is deposed during the manufacturing, the material having a small modulus is vulnerable to heat so that the substrate may be damaged by a high temperature generated during the process of forming transistors or display elements, for example, a temperature of 100° C. or higher.

Therefore, it is possible to suppress the damage of the substrate during the process of forming a display element by forming the display element above a substrate formed of a material which is tolerable to the high temperature. Therefore, there is an attempt to form the substrate using a material which is tolerable to the high temperature generated during the manufacturing process, such as polyimide (PI). However, since the materials which are tolerable to the high temperature have a large modulus, there is a problem in that the materials do not have a malleability so that the substrate is hardly bent or stretched during the process of drawing the stretchable display device.

Therefore, in the stretchable display device 100 according to the first example embodiment of the present disclosure, the plurality of island substrates 111 which are rigid substrates is disposed only in an area where the transistor 150 or the LED 160 is disposed. Therefore, the damage of the plurality of island substrates 111 due to the high temperature when the transistor 150 or the LED 160 is manufactured may be avoided.

Further, in the stretchable display device 100 according to the first example embodiment of the present disclosure, the lower substrate 110 and the upper substrate 120 which are flexible substrates may be disposed below and above the plurality of island substrates 111. Therefore, the remaining area of the lower substrate 110 and the upper substrate 120 excluding the area overlapping the plurality of island substrates 111 may be easily stretched and bent, so that the stretchable display device 100 may be implemented. Further, the transistor 150 and the organic light emitting diode 160 disposed above the plurality of island substrates 111 which is rigid substrates may be suppressed from being damaged as the stretchable display device 100 is bent or stretched.

In the meantime, when the stretchable display device is bent or stretched, the lower substrate which is formed of a flexible substrate is deformed, but the island substrates which are formed of a rigid substrate with an organic light emitting diode disposed thereon may not be deformed. In this case, when the wiring line which connects the pads disposed on the plurality of island substrates is not formed of a material which is easily bent or stretched, the wiring line may be easily cracked due to the deformation of the lower substrate to be damaged.

In contrast, in the stretchable display device 100 according to the first example embodiment of the present disclosure, the pads disposed in the plurality of island substrates 111 may be electrically connected by the connection line 180 including the base polymer and the conductive particles. The base polymer has a malleability which allows the base polymer to be easily deformed. Therefore, even though the stretchable display device 100 according to the first example embodiment of the present disclosure is bent or stretched to be deformed, the area between the plurality of island substrates 111 of the connection line 180 including the base polymer may be easily deformed.

Further, in the stretchable display device 100 according to the first example embodiment of the present disclosure, the connection line 180 includes the conductive particles so that damage such as cracks may not be caused in the conductive path formed by the conductive particles even though the base polymer is deformed. For example, when the stretchable display device 100 is bent or stretched to be deformed, the lower substrate 110 which is a flexible substrate may be deformed in the remaining area excluding an area where the plurality of island substrates 111 which are rigid substrates is disposed. In this case, the distance between the plurality of conductive particles disposed above the lower substrate 110 which is deformed may be changed. In this case, the concentration of the plurality of conductive particles which are disposed above the base polymer to form the conductive path may be maintained to be high so that even though the distance between the plurality of conductive particles is increased, the electrical signal may be transmitted. Therefore, even though the base polymer is bent or stretched, the conductive path by the plurality of conductive particles may smoothly transmit the electrical signal. Further, even though the stretchable display device 100 is bent or stretched to be deformed, the electrical signal may be transmitted between the pads.

In the stretchable display device 100 according to the first example embodiment of the present disclosure, the connection line 180 includes the base polymer and the conductive particles. Therefore, the connection line 180 which connects the pads disposed on the plurality of island substrates 111 adjacent to each other may be formed to have a shortest distance, that is, disposed to have a linear shape. That is, even though the connection line 180 is not formed to have a curved shape, the stretchable display device 100 may be implemented. The conductive particles of the connection line 180 are dispersed in the base polymer to form the conductive path. Further, as the stretchable display device 100 is bent or stretched to be deformed, the conductive path by the conductive particles may be bent or stretched. In this case, only the distance between the conductive particles is changed, but the conductive path formed by the conductive particles may still transmit the electrical signal. Therefore, in the stretchable display device 100 according to the first example embodiment of the present disclosure, the space occupied by the connection line 180 may be minimized or reduced.

Generally, in the stretchable display device, when the user extends or bends the stretchable display device so that the stretchable display device is stretched, the distance between pixels is increased so that the number of pixels per unit area is reduced. Therefore, the resolution is degraded and the image may be distorted.

Further, the lower substrate or the upper substrate is a flexible substrate to be bent or stretched, but there is a limit to the tensile strength, so that if the stretchable display device is stretched beyond the tensile strength, there is a possibility of damages of the flexible substrate and display elements.

Accordingly, in the stretchable display device 100 according to the first example embodiment of the present disclosure, a flexible viewing angle panel WP having a structure 190 which is deformed if it is stretched may be disposed above the display panel DP. Accordingly, the tensile strength of the stretchable display device 100 is suppressed from being exceeded when being stretched, so that it is possible to suppress the damage or breakage of the display panel DP due to stretching.

For example, the viewing angle panel WP may be disposed over the display element area DA, the first wiring area WA1, the second wiring area WA2, and the transparent area TA.

In the meantime, the adhesive layer 193 may be disposed between the display panel SP and the viewing angle panel WP, but is not limited thereto. The display panel DP and the viewing angle panel WP may be bonded by the adhesive layer 193. However, the present disclosure is not limited thereto and the adhesive layer 193 may be omitted according to the example embodiment. For example, the adhesive layer 193 may include an optically clear adhesive (OCA) or configured by a rubber-based adhesive, an acrylic-based adhesive, or a silicon-based adhesive.

The viewing angle panel WP may include a substrate 191, a plurality of structures 190 disposed on the substrate 191, and a protection layer 192 which covers the plurality of structures 190 and is disposed on the substrate 191.

The substrate 191 is a configuration for supporting and protecting the plurality of structures 190 and the protection layer 192. The substrate 191 is a flexible substrate and may be configured by an insulating material which is bendable or stretchable.

For example, the substrate 191 may be formed of a silicon rubber such as polydimethylsiloxane (PDMS) or an elastomer such as polyurethane (PU) or polytetrafluoroethylene (PTFE) and thus have a flexible property. However, the material of the substrate 191 is not limited thereto.

The substrate 191 is a flexible substrate so as to be reversibly expanded and contracted. Further, an elastic modulus of the substrate 191 may be several MPa to several hundreds of MPa and a ductile breaking rate may be 100% or higher. For example, a thickness of the substrate 191 may be 10 μm to 1 mm, but is not limited thereto.

For example, the substrate 191 may be disposed over the display element area DA, the first wiring area WA1, the second wiring area WA2, and the transparent area TA.

The plurality of structures 190 may be disposed on the substrate 191. At this time, for example, similar to the substrate 191, the structure 190 may be formed of a silicon rubber such as polydimethylsiloxane (PDMS) or an elastomer such as polyurethane (PU) or polytetrafluoroethylene (PTFE).

A process of forming the plurality of structures 190 on the substrate 191 is as follows.

First, in a semi-cured state of the substrate 191, the substrate 191 is stretched in one direction. For example, one direction may be an X-axis direction.

For example, the substrate 191 may be formed of a silicon rubber such as polydimethylsiloxane (PDMS) or an elastomer such as polyurethane (PU) or polytetrafluoroethylene (PTFE).

The printing is performed on the substrate 191 which is stretched as described to form the plurality of structures 190 on the substrate 191.

For example, the plurality of structures 190 may be patterned by the imprinting manner. Further, for example, the plurality of structures 190 may be formed to be parallel to each other in the Y-axis direction perpendicular to one direction.

At this time, the plurality of structures 190 may be formed on the substrate 191 in a stretched state. For example, the plurality of structures 190 is formed in parallel in the Y-axis direction and may be formed on the substrate 191 having a trapezoidal cross-section in which a width of the top base is larger than the width of the bottom side, but is not limited thereto.

Next, the protection layer 192 is formed with a low refractive material above the substrate 191 on which the plurality of structures 190 is formed. For example, the protection layer 192 is formed by being coated with the low refractive material or may be formed by attaching a low refractive optically clear adhesive (OCA).

The structure 190 and the protection layer 192 may have different refractive indices. In the case of the first example embodiment of the present disclosure, a refractive index n1 of the structure 190 may be larger than a refractive index n2 of the protection layer 192, but the present disclosure is not limited thereto.

The substrate 191 and the protection layer 192 may have different moduli. In the case of the first example embodiment of the present disclosure, a modulus m1 of the substrate 191 may be larger than a modulus m2 of the protection layer 192, but the present disclosure is not limited thereto.

The shape of the plurality of structures 190 may be changed before being stretched and after being stretched.

When the stretching is performed in the horizontal direction (X-axis direction), the structure 190 of the first example embodiment may be disposed in a direction which is substantially perpendicular to the stretched direction (Y-axis direction) (see FIGS. 3 and 4). For example, the plurality of structures 190 may be disposed to be parallel to the second connection line 182. A plurality of structures 190 may be disposed with a predetermined interval.

Accordingly, the plurality of structures 190 may be disposed so as to overlap the second connection line 182 along the second connection line 182. Further, the plurality of structures 190 may be disposed across the first connection line 181, but is not limited thereto.

For example, the plurality of structures 190 has a rectangular or square cross-sectional shape parallel in one direction (that is, a Y-axis direction) before being stretched (see FIGS. 3 and 4), but has a trapezoidal cross-sectional shape in which the top base is wider than the bottom base after being stretched (see FIGS. 5 and 6).

As described above, in the stretchable display device 100 of the first example embodiment of the present disclosure, the cross-section of the structure 190 is deformed to a trapezoidal shape in which the top base is wider than the bottom base to diffuse light emitted from the LED 160, like a lens. In this case, the viewing angle is expanded and the degradation of the resolution due to the stretching of the stretchable display device may be improved. That is, the number of physical pixels PX is compensated by the diffusion of light emitted from the LED 160 so that the degradation of the resolution due to the stretching of the stretchable display device may be improved and the image distortion may be minimized or reduced.

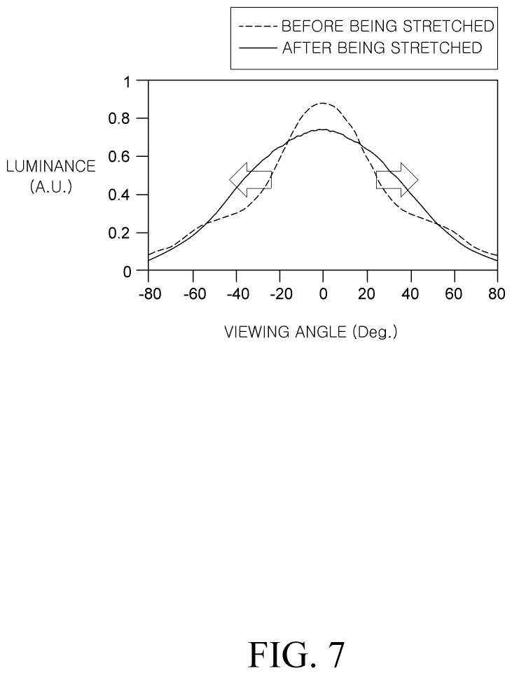

FIG. 7 is a graph illustrating a luminance according to a viewing angle.

FIG. 7 illustrates a comparison result of luminance according to a viewing angle obtained before being stretched and after being stretched.

Referring to FIG. 7, it is understood that as the luminance according to a viewing angle after being stretched, the lateral luminance is improved by the diffusion of light. Therefore, the viewing angle is expanded in a side direction.

As described above, when the viewing angle panel having the structure of the present disclosure is applied, a cross-section of the structure after being stretched is changed to the trapezoidal shape in which the top base is wider than the bottom base to diffuse the light emitted from the LED, like a lens.

In the meantime, the present disclosure is also applied to a case in which the stretching is performed in a vertical direction (that is, Y-axis direction), which will be described in detail with reference to the second example embodiment of the present disclosure.

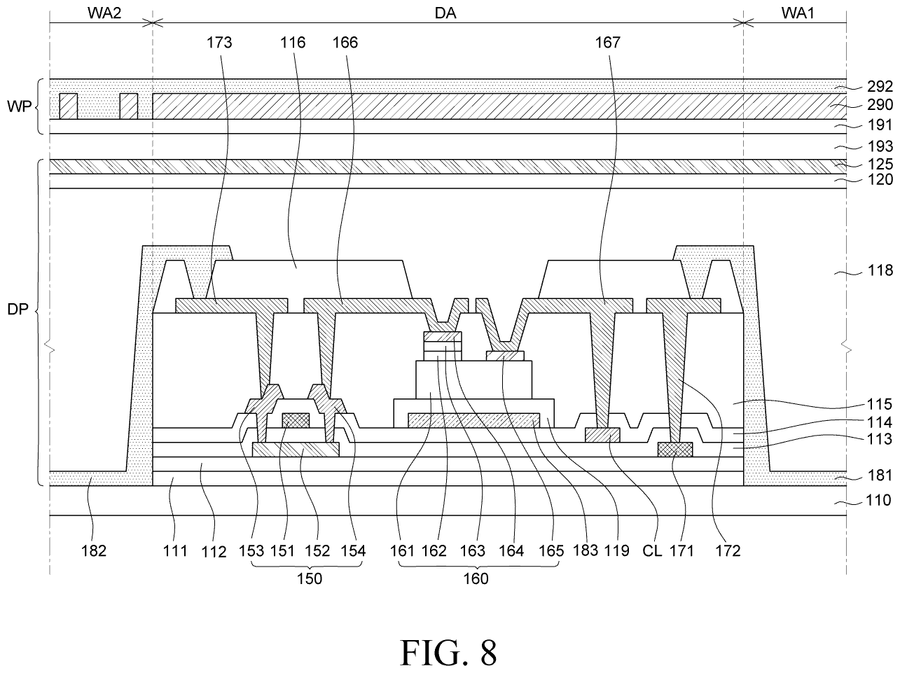

FIG. 8 is a cross-sectional view of a stretchable display device according to a second example embodiment of the present disclosure.

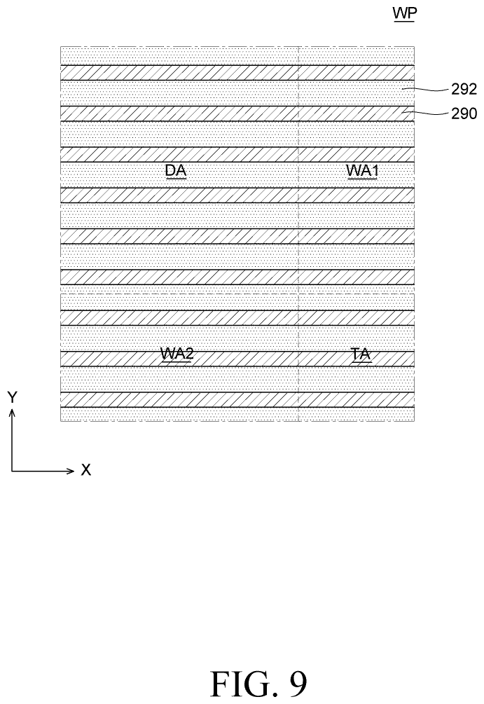

FIG. 9 is a plan view of a viewing angle panel of a stretchable display device of FIG. 8.

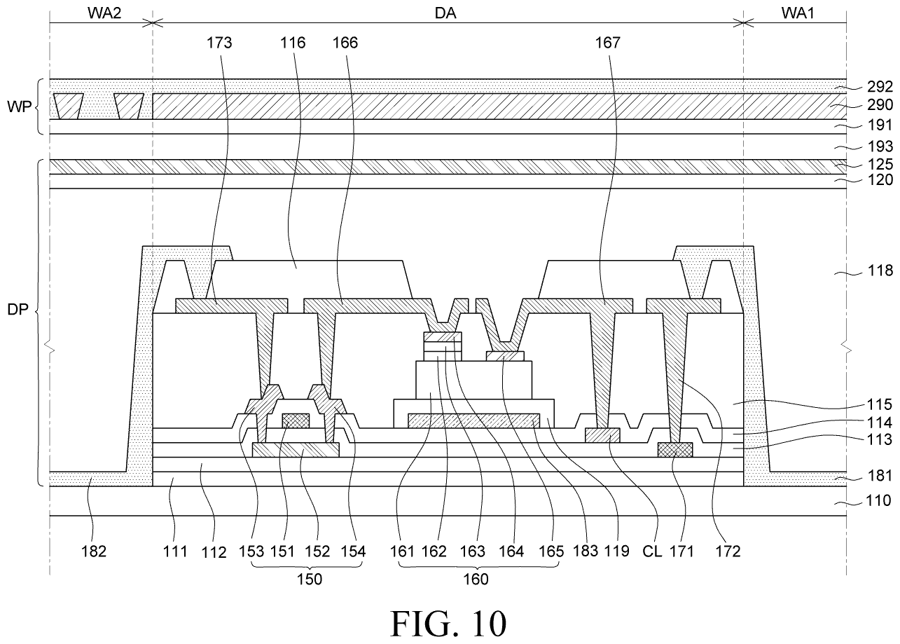

FIG. 10 is a cross-sectional view of a stretchable display device of FIG. 8 after being stretched.

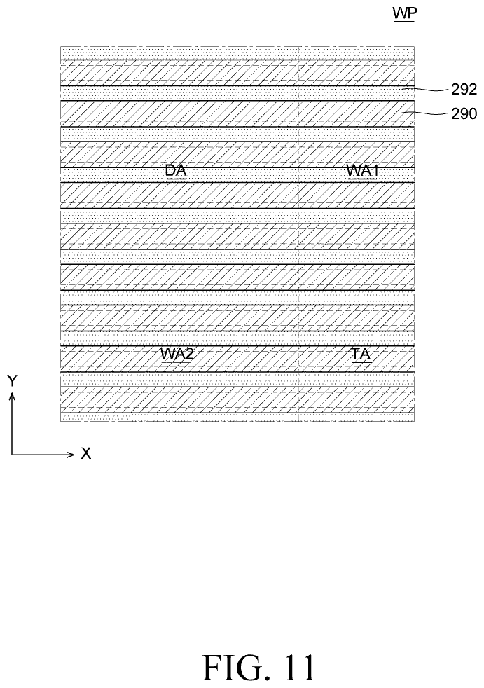

FIG. 11 is a plan view of a viewing angle panel of FIG. 9 after being stretched.

FIGS. 8 to 11 illustrate a stretchable display device of a second example embodiment of the present disclosure when the stretching is performed in a vertical direction (that is, a Y-axis direction) as an example. In this case, the structure may be disposed in a direction substantially perpendicular to the stretching direction (that is, an X-axis direction).

FIGS. 8 and 10 are cross-sectional views taken along the same direction as A-A′ of FIG. 2.

FIG. 9 is a schematic plan view of a viewing angle panel corresponding to one sub pixel in the stretchable display device of FIG. 8.

FIGS. 10 and 11 are a cross-sectional view of a stretchable display device and a plan view of a viewing angle panel after being stretched when the stretching is performed in the vertical direction (that is, the Y-axis direction).

The difference between the second example embodiment of the present disclosure of FIGS. 8 to 11 and the first example embodiment of the present disclosure of FIGS. 2 to 6 is a stretching direction and a placement direction of a structure, but the other configuration is substantially the same so that a redundant description will be omitted. The same configuration will be denoted with the same reference numeral. Here, the description for the same reference numeral may refer to FIGS. 1 to 6.

Referring to FIGS. 8 to 11, a plurality of island substrates 111 may be disposed on the lower substrate 110. The plurality of island substrates 111 is spaced apart from each other to be disposed on the lower substrate 110.

As described above, one sub pixel SPX may include the display element area DA, the first wiring area WA1, the second wiring area WA2, and the transparent area TA.

The plurality of island substrates 111 may be disposed in the display element area DA.

The transistor 150 may be disposed above the plurality of island substrates 111.

The transistor 150 may be disposed in the display element area DA.

The LED 160 may be disposed above the plurality of island substrates 111.

The LED 160 may be disposed in the display element area DA.

In the meantime, the first connection line 181 may be disposed in the first wiring area WA1.

Further, the second connection line 182 may be disposed in the second wiring area WA2.

As described above, the upper substrate 120, the polarization layer 125, and an upper adhesive layer 118 may be disposed above the lower substrate 110.

Further, a flexible viewing angle panel WP having a structure 290 according to the second example embodiment of the present disclosure which is deformed during the stretching may be disposed above the display panel DP configured as described above.

The adhesive layer 193 may be disposed between the display panel DP and the viewing angle panel WP.

For example, the viewing angle panel WP may be disposed over the display element area DA, the first wiring area WA1, the second wiring area WA2, and the transparent area TA.

For example, the viewing angle panel WP according to the second example embodiment of the present disclosure may include a substrate 191, a plurality of structures 290 disposed on the substrate 191, and a protection layer 292 which covers the plurality of structures 290 and is disposed on the substrate 191.

The plurality of structures 290 may be disposed on the substrate 191. At this time, for example, similar to the substrate 191, the structure 290 may be formed of a silicon rubber such as polydimethylsiloxane (PDMS) or an elastomer such as polyurethane (PU) or polytetrafluoroethylene (PTFE).

The structure 290 and the protection layer 292 may have different refractive indices. In the case of the second example embodiment of the present disclosure, a refractive index n1 of the structure 290 may be larger than a refractive index n2 of the protection layer 192, but the present disclosure is not limited thereto.

The substrate 191 and the protection layer 292 may have different moduli. In the case of the second example embodiment of the present disclosure, a modulus m1 of the substrate 191 may be larger than a modulus m2 of the protection layer 292, but the present disclosure is not limited thereto.

The shape of the plurality of structures 290 may be changed before being stretched and after being stretched.

When the stretching is performed in the vertical direction (Y-axis direction), the structure 290 of the second example embodiment may be disposed in a direction which is substantially perpendicular to the stretched direction (X-axis direction). For example, the plurality of structures 290 may be disposed to be parallel to the first connection line 181. A plurality of structures 290 may be disposed with a predetermined interval.

Accordingly, the plurality of structures 290 may be disposed so as to overlap the first connection line 181 along the first connection line 181. Further, the plurality of structures 290 may be disposed across the second connection line 182, but is not limited thereto.

For example, the plurality of structures 290 has a rectangular or square cross-sectional shape parallel in one direction (that is, a X-axis direction) before being stretched (see FIGS. 8 and 9), but has a trapezoidal cross-sectional shape in which the top base is wider than the bottom base after being stretched (see FIGS. 10 and 11).

As described above, even though the stretchable display device of the second example embodiment of the present disclosure is stretched in the vertical direction (that is, a Y-axis direction), since the structure 290 is disposed in a direction (that is, a X-axis direction) substantially perpendicular to the stretching direction, the cross-section of the structure 290 is deformed to be a trapezoidal shape in which a top base is wider than a bottom base. Therefore, light emitted from the LED 160 may be diffused. In this case, the viewing angle is expanded and the degradation of the resolution due to the stretching of the stretchable display device may be improved.

In the meantime, the first and second example embodiments described above may be applied when the stretching is performed in any one of the X-axis or the Y-axis, but is not limited thereto. Accordingly, the present disclosure is applied when the stretching is performed in an arbitrary direction, which will be described in detail with reference to the following third example embodiment.

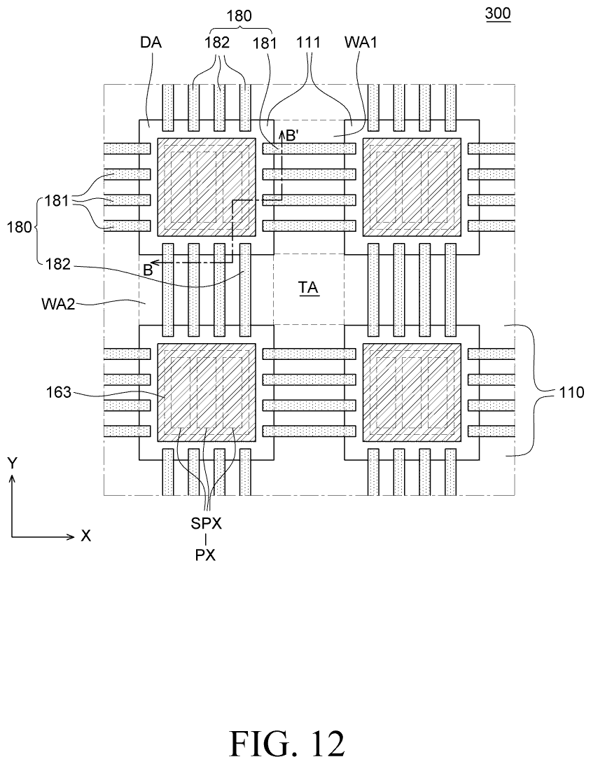

FIG. 12 is a plan view of a stretchable display device according to a third example embodiment of the present disclosure.

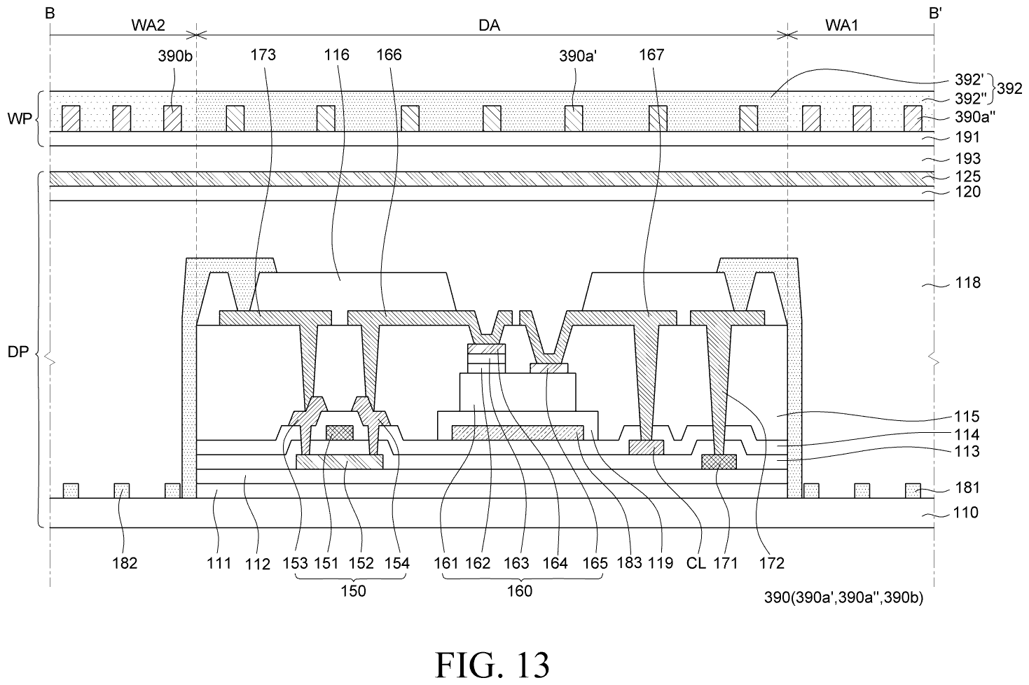

FIG. 13 is a cross-sectional view taken along the line B-B′ of FIG. 12.

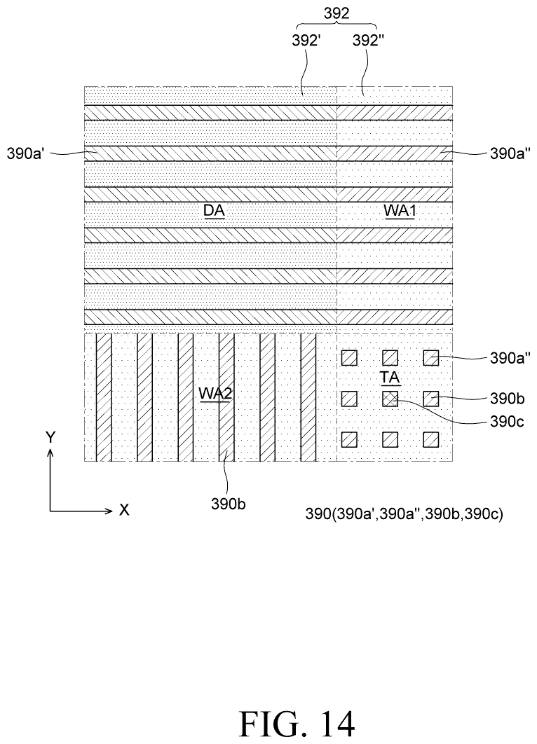

FIG. 14 is a plan view of a viewing angle panel of a stretchable display device of FIG. 13.

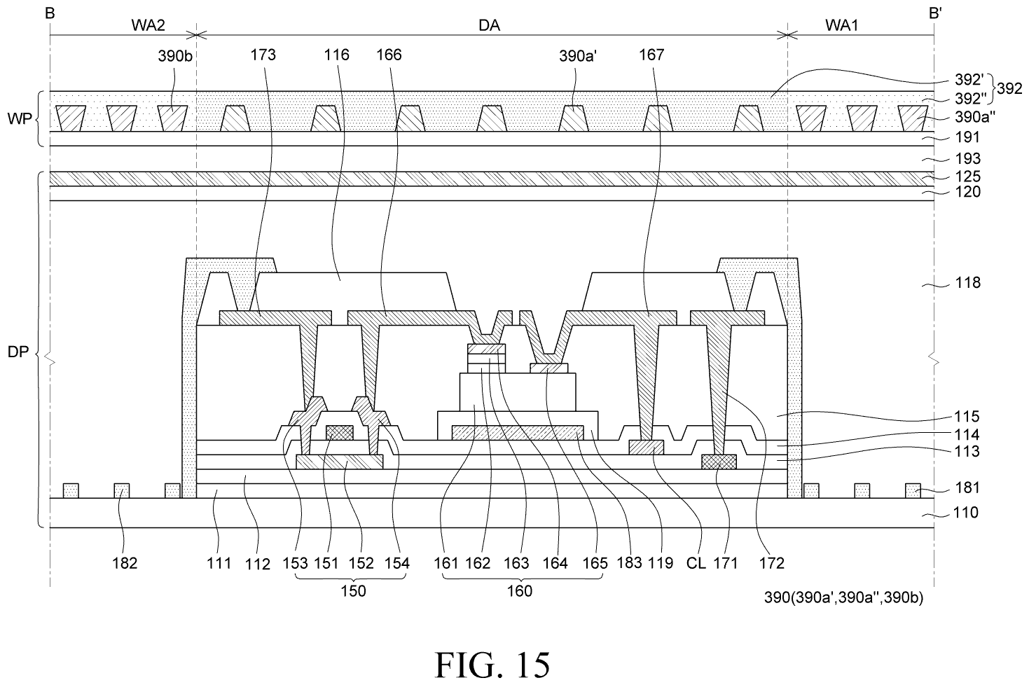

FIG. 15 is a cross-sectional view of a stretchable display device of FIG. 13 after being stretched.

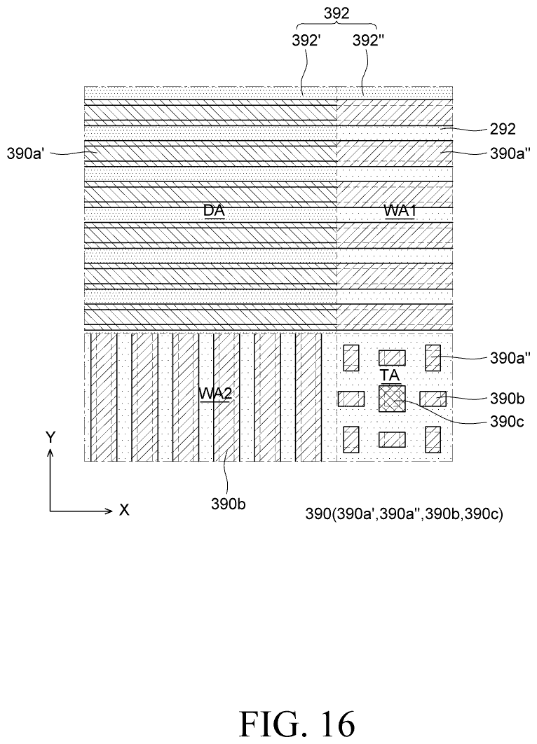

FIG. 16 is a plan view of a viewing angle panel of FIG. 14 after being stretched.

FIGS. 12 to 16 illustrate a stretchable display device of a third example embodiment of the present disclosure when the stretching is performed in an arbitrary direction as an example.

FIG. 14 is a schematic plan view of a viewing angle panel corresponding to one sub pixel in the stretchable display device of FIG. 13.

FIGS. 15 and 16 are cross-sectional views of a stretchable display device and a plan view of a viewing angle panel after being stretched when the stretching is performed in an arbitrary direction.

The difference between the third example embodiment of the present disclosure of FIGS. 12 to 16 and the first example embodiment of the present disclosure of FIGS. 2 to 6 and the second example embodiment of the present disclosure of FIGS. 8 to 11 is a shape and a placement direction of a structure according to a position of a sub pixel. However, the other configuration is substantially the same so that a redundant description will be omitted. The same configuration will be denoted with the same reference numeral. Here, the description for the same reference numeral may refer to FIGS. 1 to 11.

Referring to FIGS. 12 to 16, as described above, a sub pixel SPX of a third example embodiment of the present disclosure may include the display element area DA, the first wiring area WA1, the second wiring area WA2, and the transparent area TA.

In the display element area DA, an island substrate 111, a display element, such as an LED 160, and various driving elements such as a transistor 150 may be disposed.

The plurality of sub pixels SPX may be connected to various wiring lines, respectively. For example, the plurality of sub pixels SPX may be connected to various wiring lines such as a gate line, a data line, a high potential power source line, a low potential power source line, and a reference voltage line.

In the meantime, the first wiring area WA1 is disposed on one side of the display element area DA and may be disposed between the display element areas DA adjacent in the X-axis direction.

The first connection line 181 may be disposed in the first wiring area WA1. The first connection line 181 refers to a wiring line extending in the X-axis direction, among the connection lines 180. Therefore, the first wiring area WA1 may be a horizontal stretching area.

The first connection line 181 may connect pads above two island substrates 111 which are disposed in parallel, among pads above the plurality of island substrates 111 adjacent to each other in the X-axis direction. The first connection line 181 may serve as a gate line or a low potential power line, but is not limited thereto.

Further, the second wiring area WA2 is disposed on the other side of the display element area DA and is disposed between the display element areas DA adjacent in the Y-axis direction.

The second connection line 182 may be disposed in the second wiring area WA2. The second connection line 182 refers to a wiring line extending in the Y-axis direction, among the connection lines 180. Therefore, the second wiring area WA2 may be a vertical stretching area.

The second connection line 182 may connect pads above two island substrates 111 which are disposed in parallel, among pads above the plurality of island substrates 111 adjacent to each other in the Y-axis direction. The second connection line 182 may serve as a data line, a high potential power line, or a reference voltage line, but is not limited thereto.

Further, the transparent area TA may be disposed between the first wiring areas WA1 adjacent in the Y-axis direction and between the second wiring area WA2 adjacent in the X-axis direction.

In the transparent area TA, opaque components are not provided and the lower substrate 110 formed of elastomer is disposed so that the transparent area may be translucent. The transparent area TA may be a horizontal and vertical stretching area.

As described above, the upper substrate 120, the polarization layer 125, and an upper adhesive layer 118 may be disposed above the lower substrate 110.

Further, a flexible viewing angle panel WP having a structure 390 according to the third example embodiment of the present disclosure which is deformed during the stretching may be disposed above the display panel DP configured as described above.

The adhesive layer 193 may be disposed between the display panel DP and the viewing angle panel WP.

For example, the viewing angle panel WP may be disposed over the display element area DA, the first wiring area WA1, the second wiring area WA2, and the transparent area TA.

For example, the viewing angle panel WP according to the third example embodiment of the present disclosure may include a substrate 191, a plurality of structures 390 disposed on the substrate 191, and a protection layer 392 which covers the plurality of structures 390 and is disposed on the substrate 191.

The plurality of structures 390 may be disposed on the substrate 191. At this time, for example, similar to the substrate 191, the structure 390 may be formed of a silicon rubber such as polydimethylsiloxane (PDMS) or an elastomer such as polyurethane (PU) or polytetrafluoroethylene (PTFE).

For example, the structure 390 of the third example embodiment of the present disclosure may include first structures 390a′ and 390a″, a second structure 390b, and a third structure 390c. The first structures are deformed in a vertical direction (that is, the Y-axis direction) during stretching, the second structure is deformed in a horizontal direction (that is, the X-axis direction) during stretching, and the third structure is deformed in the horizontal direction and the vertical direction during the stretching.

For example, the protection layer 392 may include a first protection layer 392′ disposed in the display element area DA and a second protection layer 392″ disposed in the first wiring area WA1, the second wiring area WA2, and the transparent area TA.

For example, the first structures 390a′ and 390a″ may include a 1-1-th structure 390a′ disposed in the display element area DA and the 1-2-th structure 390a″ disposed in the first wiring area WA1 and the transparent area TA.

Further, the second structure 390b may be disposed in the second wiring area WA2 and the transparent area TA.

Further, the third structure 390c may be disposed in the transparent area TA.

Further, for example, the 1-1-th structure 390a′ may be deformed to a trapezoidal cross-sectional shape in which the top base is narrower than the bottom base during stretching.

In contrast, a 1-2-th structure 390a″, a second structure 390b, and the third structure 390c may be deformed to a trapezoidal cross-sectional shape in which the top base is wider than the bottom base during stretching.

As described above, according to the third example embodiment of the present disclosure, a structure 390 having a different placement direction and deformation direction is disposed depending on a position of the sub pixel SPX.

For example, in the display element area DA, a 1-1-th structure 390a′ may be disposed in the X-axis direction. In this case, the 1-1-th structure 390a′ may have a rectangular or square cross-sectional shape parallel to one direction, for example, to the X-axis direction before being stretched (see FIGS. 13 and 14). However, it is not limited thereto and the 1-1-th structure 390a′ may have a rectangular or square cross-sectional shape parallel to the Y-axis direction. Further, the 1-1-th structure 390a′ is parallel to one direction as a whole, but may also be disposed in a zigzag form. Further, the 1-1-th structure 390a′ may be disposed with an angle of approximately 0 to 10 degrees in the X-axis direction.

Further, the 1-1-th structure 390a′ may be configured to be deformed to a trapezoidal cross-sectional shape in which the top base is narrower than the bottom base during the stretching to collect light emitted from the LED 160 (see FIGS. 15 and 16).

The 1-1-th structure 390a′ and the first protection layer 392′ may have different refractive indices. The refractive index n1 of the 1-1-th structure 390a′ is smaller than the refractive index n2 of the first protection layer 392′. For example, the refractive index n1 of the 1-1-th structure 390a′ has a value of 1.3<n1<1.5 and the refractive index n2 of the first protection layer 392′ may have a value of 1.5<n2<1.7, but are not limited thereto.

For example, a pitch between the 1-1-th structures 390a′ may have a value of 15 μm or smaller. Further, an interval S between the 1-1-th structures 390a′ may have a value of 5 μm<S<10 μm. Further, a height H of the 1-1-th structure 390a′ may have a value of 1 μm<H<10 μm. Further, a length Lu of the top base of the 1-1-th structure 390a′ may have a value of 2 μm<Lu<7 μm and a length Lb of the bottom base may have a value of 10 μm<Lb<14 μm.

The substrate 191 and the first protection layer 392′ may have different moduli.

According to the third example embodiment of the present disclosure, a modulus m1 of the substrate 191 may be smaller than a modulus m2 of the first protection layer 392′, but the present disclosure is not limited thereto.

Therefore, the 1-1-th structure 390a′ of the third example embodiment of the present disclosure may have deformed to a trapezoidal cross-sectional shape in which the top base is narrower than the bottom base after being stretched (see FIGS. 15 and 16).

Therefore, light emitted from the LED 160 is collected in the display element area DA to allow clearer images to be seen.

For example, in the first wiring area WA1, a 1-2-th structure 390a″ may be disposed in the X-axis direction. In this case, the 1-2-th structure 390a″ has a rectangular or square cross-sectional shape parallel to one direction, for example, in the X-axis direction before being stretched (see FIGS. 13 and 14). However, it is not limited thereto and the 1-2-th structure 390a″ may have a rectangular or square cross-sectional shape parallel to the Y-axis direction. Further, the 1-2-th structure 390a″ is parallel to one direction as a whole, but may also be disposed in a zigzag form. Further, the 1-2-th structure 390a″ may be disposed with an angle of approximately 0 to 10 degrees in the X-axis direction.

For example, the 1-2-th structure 390a″ may be disposed to be parallel to the first connection line 181. A plurality of 1-2-th structures 390a″ may be disposed with a predetermined interval.

Accordingly, for example, the plurality 1-2-th structures 390a″ may be disposed so as to overlap the first connection line 181 along the first connection line 181.

Further, the 1-2-th structure 390a″ may be configured to be deformed to a trapezoidal cross-sectional shape in which the top base is wider than the bottom base during the stretching to diffuse light emitted from the LED 160 (see FIGS. 15 and 16).

The 1-2-th structure 390a″ and the second protection layer 392″ may have different refractive indices.

The refractive index n3 of the 1-2-th structure 390a″ may be larger than the refractive index n4 of the second protection layer 392″. For example, the refractive index n3 of the 1-2-th structure 390a″ has a value of 1.5<n3<1.7 and the refractive index n4 of the second protection layer 392″ has a value of 1.3<n4<1.5, but are not limited thereto.

For example, a pitch between the 1-2-th structures 390a″ may have a value of 15 μm or smaller. Further, an interval S between the 1-2-th structures 390a″ may have a value of 5 μm<S<10 μm. Further, a height H of the 1-2-th structure 390a″ may have a value of 1 μm<H<10 μm. Further, a length Lu of the top base of the 1-2-th structure 390a″ may have a value of 10 μm<Lu<14 μm and a length Lb of the bottom base may have a value of 2 μm<Lb<7 μm.

In the meantime, the second structure 390b may be disposed in the Y-axis direction in the second wiring area WA2. In this case, the second structure 390b may have a rectangular or square cross-sectional shape parallel to one direction, for example, the Y-axis direction before being stretched (see FIGS. 13 and 14). However, it is not limited thereto and the second structure 390b may have a rectangular or square cross-sectional shape parallel to the X-axis direction. Further, the second structure 390b is parallel to one direction as a whole, but may also be disposed in a zigzag form. Further, the second structure 390b may be disposed with an angle of approximately 0 to 10 degrees in the Y-axis direction.

For example, the second structure 390b may be disposed to be parallel to the second connection line 182. A plurality of second structures 390b may be disposed with a predetermined interval.

Accordingly, the plurality of second structures 390b may be disposed so as to overlap the second connection line 182 along the second connection line 182.

Further, the second structure 390b is configured to be deformed to a trapezoidal cross-sectional shape in which the top base is wider than the bottom base during the stretching to diffuse light emitted from the LED 160 (see FIGS. 15 and 16).

The second structure 390b and the second protection layer 392″ may have different refractive indices.

The refractive index n3 of the second structure 390b may be larger than the refractive index n4 of the second protection layer 392″. For example, the refractive index n3 of the second structure 390b has a value of 1.5<n3<1.7 and the refractive index n4 of the second protection layer 392″ has a value of 1.3<n4<1.5.

For example, a pitch between the second structures 390b may have a value of 15 μm or smaller. Further, an interval S between the second structures 390b may have a value of 5 μm<S<10 μm. Further, a height H of the second structure 390b may have a value of 1 μm<H<10 μm. Further, a length Lu of the top base of the second structure 390b may have a value of 10 μm<Lu<14 μm and a length Lb of the bottom base may have a value of 2 μm<Lb<7 μm.

Further, in the first wiring area WA1 and the second wiring area WA2, the substrate 191 and the second protection layer 392″ have different moduli.

According to the third example embodiment of the present disclosure, a modulus m1 of the substrate 191 may be larger than a modulus m2 of the second protection layer 392″, but the present disclosure is not limited thereto.

Therefore, the 1-2-th structure 390a″ and the second structure 390b of the third example embodiment of the present disclosure may be deformed to a trapezoidal cross-sectional shape in which the top base is wider than the bottom base after being stretched (see FIGS. 15 and 16).

Accordingly, light emitted from the LED 160 is diffused vertically and horizontally in the first wiring area WA1 and the second wiring area WA2 to expand the viewing angle and improve the degradation of resolution caused by the stretching of the stretchable display device.

Further, according to the third example embodiment of the present disclosure, the 1-2-th structure 390a″ and the second structure 390b are disposed so as to correspond to upper portions of the first connection line 181 of the first wiring area WA1 and the second connection line 182 of the second wiring area WA2. By doing this, the yellowish reflective visibility due to the connection line 180 may be improved.

In the meantime, in the transparent area TA, the 1-2-th structure 390a″, the second structure 390b, and the third structure 390c may be disposed. The 1-2-th structure 390a″, the second structure 390b, and the third structure 390c disposed in the transparent area TA have a rectangular or square cross-sectional shape before being stretched (see FIGS. 13 and 14). For example, the plurality of 1-2-th structures 390a″, second structures 390b, and third structures 390c may be randomly disposed.

The third structure 390c and the second protection layer 392″ may have different refractive indices.

The refractive index n5 of the third structure 390c may be larger than the refractive index n4 of the second protection layer 392″. For example, the refractive index n5 of the third structure 390c has a value of 1.5<n5<1.7 and the refractive index n4 of the second protection layer 392″ may have a value of 1.3<n4<1.5.

A pitch between the 1-2-th structures 390a″, the second structures 390b, and the third structures 390c may have a value of 15 μm or smaller. Further, the interval S between the 1-2-th structure 390a″ and the second structure 390b and the third structures 390c may have a value of 5 μm<S<10 μm. Further, a height H of the third structure 390c may have a value of 1 μm<H<10 μm. Further, a length Lu of the top base of the third structure 390c may have a value of 10 μm<Lu<14 μm and a length Lb of the bottom base may have a value of 2 μm<Lb<7 μm.

The substrate 191 and the second protection layer 392″ in the transparent area TA may have different moduli.

Further, for example, the 1-2-th structures 390a″, the second structures 390b, and the third structures 390c of the transparent area TA may be configured to be deformed to a trapezoidal cross-sectional shape in which the top base is wider than the bottom base during the stretching to diffuse light emitted from the LED 160 (see FIGS. 15 and 16).

Therefore, an effect of diffusing light emitted from the LED 160 vertically and horizontally in the transparent area TA to expand the viewing angle is achieved and the degradation of the resolution caused by the stretching of the stretchable display device may be improved.

As described above, according to the third example embodiment of the present disclosure, not only when being stretched in one direction, such as the X-axis or the Y-axis, but also when being stretched in an arbitrary direction or various directions, light emitted from the LED 160 is diffused vertically and horizontally. Accordingly, the degradation of the resolution caused by the stretching of the stretchable display device may be effectively improved.

In the meantime, in the first to third example embodiments described above, the LED is applied as the display element as an example, but is not limited thereto. However, in the present disclosure, an organic light emitting diode is applied as the display element, which will be described in detail with reference to the following fourth example embodiment.

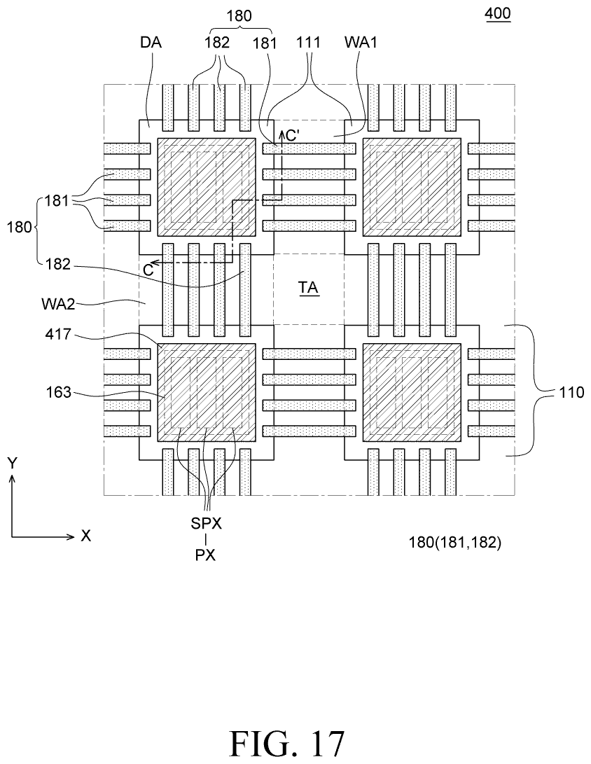

FIG. 17 is a plan view of a stretchable display device according to a fourth example embodiment of the present disclosure.

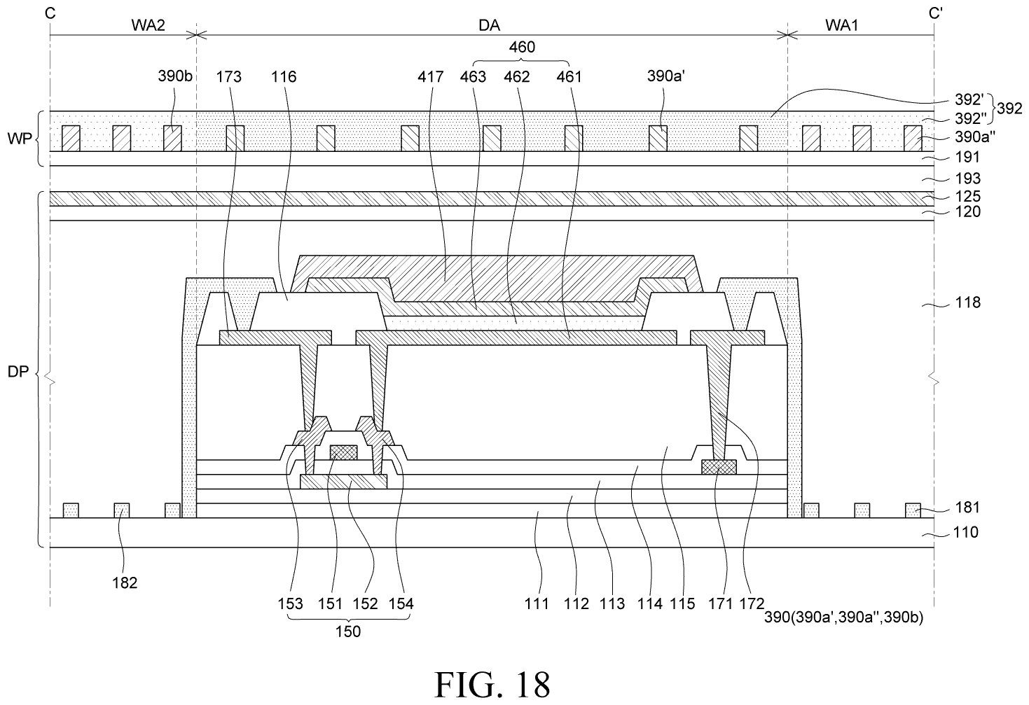

FIG. 18 is a cross-sectional view taken along C-C′ of FIG. 17.

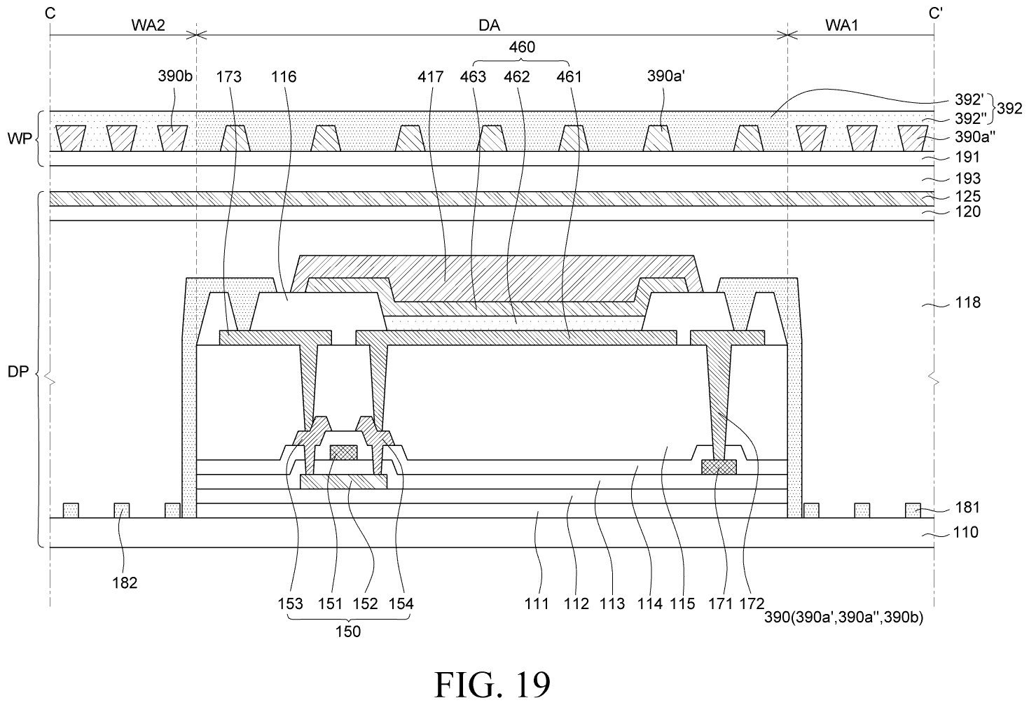

FIG. 19 is a cross-sectional view of a stretchable display device of FIG. 17 after being stretched.

FIGS. 17 to 19 illustrate a stretchable display device of a fourth example embodiment of the present disclosure when the stretching is performed in an arbitrary direction as an example.

FIG. 19 is a cross-sectional view of a stretchable display device after being stretched when the stretching is performed in an arbitrary direction.

The difference between a fourth example embodiment of the present disclosure of FIGS. 17 to 19 and the above-described third example embodiment of FIGS. 12 to 16 that the organic light emitting diode is applied as the display device, but the other configuration is substantially the same so that a redundant description will be omitted. The same configuration will be denoted with the same reference numeral. Here, the description for the same reference numeral may refer to FIGS. 1 to 16.

Referring to FIGS. 17 to 19, a plurality of island substrates 111 may be disposed on the lower substrate 110 as described above.

A buffer layer 112 may be disposed on the plurality of island substrates 111.

A transistor 150 including a gate electrode 151, an active layer 152, a source electrode 153, and a drain electrode 154 may be formed above the buffer layer 112.

A gate pad 171 may be disposed on the gate insulating layer 113.

The planarization layer 115 may be disposed above the transistor 150 and the interlayer insulating layer 114. The planarization layer 115 planarizes an upper portion of the transistor 150. The planarization layer 115 may be configured by a single layer or a plurality of layers and may be formed of an organic material. For example, the planarization layer 115 may be formed of an acrylic-based organic material, but is not limited thereto. The planarization layer 115 may include a contact hole for electrically connecting the transistor 150 and an anode 461, a contact hole for electrically connecting the data pad 173 and the source electrode 153, and a contact hole for electrically connecting the connection pad 172 and the gate pad 171.

In some example embodiments, an additional insulating layer may be formed between the transistor 150 and the planarization layer 115. The additional insulating layer which covers the transistor 150 may be disposed to protect the transistor 150 from the permeation of the moisture and oxygen. The additional insulating layer may be formed of an inorganic material and may be formed by a single layer or a double layer. The additional insulating layer may be a passivation layer, but the present disclosure is not limited thereto.

The data pad 173, the connection pad 172, and the organic light emitting diode 460 may be disposed above the planarization layer 115.

The organic light emitting element 460 may be disposed so as to correspond to each of the plurality of sub pixels SPX and emits light having a specific wavelength band. For example, the organic light emitting diode 460 may be a blue organic light emitting diode which emits blue light, a red organic light emitting diode which emits red light, a green organic light emitting diode which emits green light, or a white organic light emitting diode which emits white light, but is not limited thereto. When the organic light emitting diode 460 is a white organic light emitting diode, the stretchable display device 400 may further include a color filter.

The organic light emitting diode 460 may include an anode 461, an organic emission layer 462, and a cathode 463. Specifically, the anode 461 may be disposed on the planarization layer 115. At this time, the anode 461 is an electrode configured to supply holes to the organic emission layer 462. The anode 461 may be configured by a transparent conductive material having a high work function. Here, the transparent conductive material may include indium tin oxide (ITO), indium zinc oxide (IZO), or indium tin zinc oxide (ITZO). The anode 461 may be formed of the same material as the data pad 173 and the gate pad 171 disposed on the planarization layer 115, but is not limited thereto. Further, when the stretchable display device 400 is implemented as a top emission type, the anode 461 may further include a reflector.

The anodes 461 are disposed to be spaced apart from each other for each of the sub pixels SPX to be electrically connected to the transistor 150 through a contact hole of the planarization layer 115. For example, in FIGS. 18 and 19, it is illustrated that the anode 461 is electrically connected to the drain electrode 154 of the transistor 150 as an example, but it is not limited thereto and the anode 461 may be electrically connected to the source electrode 153.

A bank 116 may be formed above the anode 461, the data pad 173, the connection pad 172, and the planarization layer 115. The bank 116 is a component which divides adjacent sub pixels SPX. The bank 116 is disposed so as to cover at least a part of both sides of the adjacent anode 461 to expose a part of a top surface of the anode 461. The bank 116 may suppress a problem in that a current is concentrated at the corner of the anode 461 to emit the light to the side surface of the anode 461 so that an unintended sub pixel SPX emits light or colors are mixed. For example, the bank 116 may be formed of polyimide, acrylic-based resin, or benzocyclobutene (BCB)-based resin, but is not limited thereto.

Here, the bank 116 includes a contact hole through which the connection line 180 serving as a data line and the data pad 173 are connected and a contact hole through which the connection line 180 serving as a gate line and the connection pad 172 are connected.

The organic emission layer 462 may be disposed on the anode 461. The organic emission layer 462 may be configured to emit light. The organic emission layer 462 may include a luminescent material and the luminescent material may include a phosphorescent material or a fluorescent material, but is not limited thereto.

The organic emission layer 462 is configured as one emission layer, but is not limited thereto and may have a stack structure in which a plurality of emission layers is laminated with a charge generation layer therebetween. Further, the organic emission layer 462 may further include at least one organic layer of a hole transport layer, an electron transport layer, a hole blocking layer, an electron blocking layer, a hole injection layer, and an electron injection layer.

The cathode 463 may be disposed on the organic emission layer 462. The cathode 463 may supply electrons to the organic emission layer 462. For example, the cathode 463 may be formed of transparent conductive oxide such as indium tin oxide (ITO), indium zinc oxide (IZO), indium tin zinc oxide (ITZO), zinc oxide (ZnO), and tin oxide (TO) or ytterbium (Yb) alloy. Alternatively, the cathode 463 may be formed of a metal material.

The cathode 463 may be patterned so as to overlap the plurality of island substrates 111. The cathode 463 is formed only in an area overlapping the plurality of island substrates 111 and may not be formed in an area between the plurality of island substrates 111. Since the cathode 463 is formed of a material such as a transparent conductive oxide or a metal material, when the cathode 463 is formed in the area between the plurality of island substrates 111, the cathode 463 may be damaged during the process of stretching the stretchable display device 400. Therefore, the cathode 463 may be disposed so as to correspond to each of the plurality of island substrates 111 on a flat surface. The cathode 463 is disposed so as to have an area which does not overlap an area in which the connection line 180 is disposed in an area overlapping the plurality of island substrates 111.

Unlike the general organic light emitting display device, in the stretchable display device 400 according to the fourth example embodiment of the present disclosure, the cathode 463 is patterned to be disposed so as to correspond to the plurality of island substrates 111. Therefore, the cathode 463 disposed above the plurality of island substrates 111 may be independently supplied with a low potential power through the connection line 180.

The encapsulation layer 417 may be disposed above the organic light emitting diode 460. The encapsulation layer 417 covers the organic light emitting diode 460 and is in contact with a part of the top surface of the bank 116 to seal the organic light emitting diode 460. Therefore, the encapsulation layer 417 may protect the organic light emitting diode 460 from moisture, air, or physical impact permeating from the outside.

The encapsulation layer 417 covers the cathode 463 which is patterned to overlap the plurality of island substrates 111 and may be disposed in each of the plurality of island substrates 111. The encapsulation layer 417 is disposed so as to cover one cathode 463 disposed in one island substrate 111 and the encapsulation layers 417 disposed on the plurality of island substrates 111 may be spaced apart from each other.

The encapsulation layer 417 may be formed only in an area overlapping the plurality of island substrates 111. As described above, the encapsulation layer 417 may be configured to include an inorganic layer so that the encapsulation layer may be easily cracked or damaged during a process of stretching the stretchable display device 400. Specifically, since the organic light emitting diode 460 is vulnerable to the moisture or oxygen, when the encapsulation layer 417 is damaged, the reliability of the organic light emitting diode 460 may be reduced. Therefore, in the stretchable display device 400 according to the fourth example embodiment of the present disclosure, the encapsulation layer 417 is not formed in an area between the plurality of island substrates 111. Therefore, even though the stretchable display device 400 is bent or stretched to be deformed, the damage of the encapsulation layer 417 may be minimized or reduced.

As described above, the upper substrate 120, the polarization layer 125, and the upper adhesive layer 118 may be disposed above the lower substrate 110.

Further, a flexible viewing angle panel WP having a structure 390 according to the fourth example embodiment of the present disclosure which is deformed during the stretching may be disposed above the display panel DP configured as described above.

The adhesive layer 193 may be disposed between the display panel DP and the viewing angle panel WP.

For example, the viewing angle panel WP according to the fourth example embodiment of the present disclosure may include a substrate 191, a plurality of structures 390 disposed on the substrate 191, and a protection layer 392 which covers the plurality of structures 390 and is disposed on the substrate 191. Here, the viewing angle panel WP of the fourth example embodiment is substantially the same as the viewing angle panel of the third example embodiment so that the description thereof will be omitted.

The example embodiments of the present disclosure can also be described as follows:

According to an aspect of the present disclosure, there is provided a stretchable display device. The stretchable display device includes a lower substrate, a plurality of pixels including a plurality of sub pixels, a plurality of island substrates disposed on the lower substrate and spaced apart from each other, each corresponding to a respective pixel, a plurality of connection lines which electrically connects pads disposed in adjacent island substrates among the plurality of island substrates, an upper substrate disposed above the lower substrate and a viewing angle panel disposed above the upper substrate and including a plurality of structures configured to be deformed during stretching, each sub pixel may include a display element area, a first wiring area, a second wiring area, and a transparent area.

The lower substrate and the upper substrate may have a ductility higher than the plurality of island substrates and a modulus of the plurality of island substrates may be higher than moduli of the lower substrate and the upper substrate.

In the display element area, a display element and a driving element for driving the display element may be disposed, the display element may include an LED, an organic light emitting diode, or a liquid display element, and the driving element may include a transistor.

The first wiring area may be disposed on one side of the display element area and may be disposed between the display element areas that are adjacent in one direction, and a first connection line extending in one direction may be disposed in the first wiring area.

The second wiring area may be disposed on the other side of the display element area and may be disposed between the display element areas that are adjacent in the other direction, and a second connection line extending in the other direction may be disposed in the second wiring area.

The transparent area may be disposed between the first wiring areas adjacent in the other direction and between the second wiring areas adjacent in one direction.

The viewing angle panel may be disposed over the display element area, the first wiring area, the second wiring area, and the transparent area.

The viewing angle panel may include a substrate, a plurality of structures disposed on the substrate and a protection layer which covers the plurality of structures and is disposed on the substrate.

A refractive index of the structure may be larger than a refractive index of the protection layer and a modulus of the substrate may be larger than a modulus of the protection layer.

The plurality of structures may be disposed in a direction parallel to the second connection line, the plurality of structures may be disposed to overlap the second connection line along the second connection line, and the plurality of structures may be disposed across the first connection line.

The plurality of structures may be disposed in a direction parallel to the first connection line, the plurality of structures may be disposed to overlap the first connection line along the first connection line, and the plurality of structures may be disposed across the second connection line.

The plurality of structures may have a rectangular or square cross-sectional shape before being stretched and may be deformed to have a trapezoidal cross-sectional shape in which a top base is wider than a bottom base after being stretched.

The structure may include a first structure which is deformed in the other direction when it is stretched, a second structure which is deformed in the one direction when it is stretched and a third structure which is deformed in the one direction and the other direction when it is stretched.

The protection layer may include a first protection layer disposed in the display element area and a second protection layer which is disposed in the first wiring area, the second wiring area, and the transparent area.

The first structure may include a 1-1-th structure disposed in the display element area and a 1-2-th structure disposed in the first wiring area and the transparent area.

The second structure may be disposed in the second wiring area and the transparent area and the third structure may be disposed in the transparent area.

The 1-1-th structure may be deformed to have a trapezoidal cross-sectional shape in which the top base is narrower than the bottom base when it is stretched and the 1-2-th structure, the second structure, and the third structure may be deformed to have a trapezoidal cross-sectional shape in which the top base is wider than the bottom base when they are stretched.

A refractive index of the 1-1-th structure may be smaller than a refractive index of the first protection layer and a modulus of the substrate may be smaller than a modulus of the first protection layer.

The 1-2-th structure may be disposed in a direction parallel to the first connection line, the plurality of 1-2-th structures may be disposed to overlap the first connection line along the first connection line, and the second structure may be disposed in a direction parallel to the second connection line, and the plurality of second structures may be disposed to overlap the second connection line along the second connection line.

A refractive index of the 1-2-th structure may be larger than a refractive index of the second protection layer, a refractive index of the second structure may be larger than a refractive index of the second protection layer, and a modulus of the substrate may be larger than a modulus of the second protection layer.

In the transparent area, the plurality of 1-2-th structures, second structures, and third structures may be randomly disposed.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A stretchable display device, comprising:
a lower substrate;
a plurality of pixels including a plurality of sub pixels;
a plurality of island substrates disposed on the lower substrate and spaced apart from each other, each of the plurality of island substrates corresponding to a respective pixel;
a plurality of connection lines which electrically connects pads disposed in adjacent island substrates among the plurality of island substrates;
an upper substrate disposed above the lower substrate; and
a viewing angle panel disposed above the upper substrate and including a plurality of structures configured to be deformed during stretching,
wherein each sub pixel includes a display element area, a first wiring area, a second wiring area, and a transparent area.

2. The stretchable display device according to claim 1, wherein a ductility of each of the lower substrate and the upper substrate is higher than a ductility of the plurality of island substrates, and a modulus of each of the plurality of island substrates is higher than a modulus of each of the lower substrate and the upper substrate.

3. The stretchable display device according to claim 1, wherein in the display element area, a display element and a driving element for driving the display element are disposed, the display element includes a light emitting diode (LED), an organic light emitting diode, or a liquid display element, and the driving element includes a transistor.

4. The stretchable display device according to claim 1, wherein the first wiring area is disposed on one side of the display element area and is disposed between display element areas that are adjacent in one direction, and
wherein a first connection line extending in the one direction is disposed in the first wiring area.

5. The stretchable display device according to claim 4, wherein the second wiring area is disposed on another side of the display element area and is disposed between display element areas that are adjacent in another direction, and
wherein a second connection line extending in the another direction is disposed in the second wiring area.

6. The stretchable display device according to claim 5, wherein the transparent area is disposed between first wiring areas adjacent in the another direction and between second wiring areas adjacent in one direction.

7. The stretchable display device according to claim 1, wherein the viewing angle panel is disposed over the display element area, the first wiring area, the second wiring area, and the transparent area.

8. The stretchable display device according to claim 5, wherein the viewing angle panel includes:
a substrate;
the plurality of structures disposed on the substrate; and
a protection layer which covers the plurality of structures and is disposed on the substrate.

9. The stretchable display device according to claim 8, wherein a refractive index of a structure among the plurality of structures is larger than a refractive index of the protection layer, and a modulus of the substrate is larger than a modulus of the protection layer.

10. The stretchable display device according to claim 8, wherein the plurality of structures is disposed in a direction parallel to the second connection line, the plurality of structures is disposed to overlap the second connection line along the second connection line, and the plurality of structures is disposed across the first connection line.

11. The stretchable display device according to claim 8, wherein the plurality of structures is disposed in a direction parallel to the first connection line, the plurality of structures is disposed to overlap the first connection line along the first connection line, and the plurality of structures is disposed across the second connection line.

12. The stretchable display device according to claim 10, wherein the plurality of structures has a rectangular or square cross-sectional shape before being stretched and is deformed to have a trapezoidal cross-sectional shape after being stretched, and wherein a top base is wider than a bottom base in the trapezoidal cross-sectional shape.

13. The stretchable display device according to claim 8, wherein a structure among the plurality of structures includes:
a first structure which is deformed in the another direction when the first structure is stretched;
a second structure which is deformed in the one direction when the second structure is stretched; and
a third structure which is deformed in the one direction and the another direction when the third structure is stretched.

14. The stretchable display device according to claim 13, wherein the protection layer includes:
a first protection layer disposed in the display element area; and
a second protection layer which is disposed in the first wiring area, the second wiring area, and the transparent area.

15. The stretchable display device according to claim 14, wherein the first structure includes:
a 1-1-th structure disposed in the display element area; and
a 1-2-th structure disposed in the first wiring area and the transparent area, and
wherein the second structure is disposed in the second wiring area and the transparent area, and the third structure is disposed in the transparent area.

16. The stretchable display device according to claim 15, wherein the 1-1-th structure is deformed to have a trapezoidal cross-sectional shape in which a top base is narrower than a bottom base when the 1-1-th structure is stretched, and wherein the 1-2-th structure, the second structure, and the third structure are deformed to have a trapezoidal cross-sectional shape in which the top base is wider than the bottom base when the 1-2-th structure, the second structure, and the third structure are stretched.

17. The stretchable display device according to claim 15, wherein a refractive index of the 1-1-th structure is smaller than a refractive index of the first protection layer, and a modulus of the substrate is smaller than a modulus of the first protection layer.

18. The stretchable display device according to claim 15, wherein the 1-2-th structure is disposed in a direction parallel to the first connection line, the 1-2-th structure is disposed to overlap the first connection line along the first connection line, and the second structure is disposed in a direction parallel to the second connection line, and the second structure is disposed to overlap the second connection line along the second connection line.

19. The stretchable display device according to claim 15, wherein a refractive index of the 1-2-th structure is larger than a refractive index of the second protection layer, a refractive index of the second structure is larger than a refractive index of the second protection layer, and a modulus of the substrate of the viewing angle panel is larger than a modulus of the second protection layer.

20. The stretchable display device according to claim 15, wherein in the transparent area, the 1-2-th structure, the second structure, and the third structure are randomly disposed.
